(19) United States
(12) Patent Application Publication
(10) Pub. No.: US 2023/0279030 A1
(43) Pub. Date: Sep. 7, 2023

(54) CYCLOSILOXANES AND FILMS MADE THEREWITH

(71) Applicant: VERSUM MATERIALS US, LLC, TEMPE, AZ (US)

(72) Inventors: FORREST GLENN BROWN, MESA, AZ (US); RAYMOND NICHOLAS VRTIS, CARLSBAD, CA (US); ROBERT GORDON RIDGEWAY, CHANDLER, AZ (US); MANCHAO XIAO, SAN DIEGO, CA (US); SURESH KALPATTU RAJARAMAN, TAIPEI (TW); DANIEL P. SPENCE, CARLSBAD, CA (US)

(21) Appl. No.: 18/006,659

(22) PCT Filed: Jul. 23, 2021
(86) PCT No.: PCT/US2021/042935

§ 371 Date: Jan. 24, 2023

Related U.S. Application Data
(60) Provisional application No. 63/056,310, filed on Jul. 24, 2020.

(51) Int. Cl. C07F 7/21; C23C 16/511; C23C 16/24

(52) U.S. Cl. CPC C07F 7/21; C23C 16/511; C23C 16/24

(57) ABSTRACT

A composition useful in depositing low dielectric constant (low-k) insulating materials into high aspect ratio gaps, trenches, vias, and other surface features, of semiconductor devices by a plasma-enhanced chemical vapor deposition (PECVD) process is disclosed. The composition may comprise an alkoxy-functionalized cyclosiloxane derived from trimethylcyclotrisiloxane, tetramethylcyclotetrasiloxane, or pentamethylcyclopentasiloxane. The alkoxy-functionalization may comprise between 1 and 10 carbon atoms. A method of depositing the alkoxy-functionalized cyclosiloxane composition by a PECVD process is also disclosed. Finally, a film comprising a flowable liquid, or oligomer, comprising the oligomerized, or polymerized, alkoxy-functionalized cyclosiloxane composition, on a substrate is disclosed.

### CROSS REFERENCE TO RELATED APPLICATIONS

This application is a National Stage filing under 35 U.S.C. 371 of International Patent Application No. PCT/US2021/042935 filed Jul. 23, 2021, which claims priority to the U.S. Application No. 63/056,310 filed on Jul. 24, 2020. The entire contents of these applications are incorporated herein by reference in their entirety.

### TECHNICAL FIELD

This disclosure generally relates to cyclosiloxanes, and films made therewith, and more particularly to alkoxy-functionalized cyclosiloxanes, and films made therewith.

### BACKGROUND

Semiconductor device geometries continue to decrease in size, and as such, the surface density of these devices continues to increase. With this increased density, the chance of electrical interference, including cross-talk and parasitic capacitance, between adjacent devices increases. To reduce the likelihood of this electrical interference, low dielectric constant (low-k) insulating materials are often placed in the gaps, trenches, vias, and other surface features, between adjacent devices.

A process utilized to place these low-k insulating materials between adjacent devices includes Chemical Vapor Deposition (CVD). However, as device geometries have shrunk, the corresponding aspect ratios of the gaps, trenches, vias, and other surface features, that need to be filled with the low-k insulating materials have increased. For example, the gaps, trenches, vias, and other features of current semiconductor devices, often have aspect ratios greater than 5:1, or even greater than 20:1. For better, or worse, it is not uncommon to experience voids in the resulting film, or an overgrowth of the low-k insulating material known as “breadloafing,” when utilizing CVD to deposit low-k materials in these high aspect ratio features. Both voids, and breadloafing, are defects to be avoided when depositing low-k materials in high aspect ratio gaps, trenches, vias, and other surface features.

A means to resolve voids, breadloafing, and other defects, when depositing low-k insulating materials in high aspect ratio surface features includes utilizing a process known as Flowable Chemical Vapor Deposition (FCVD). In FCVD, a low-k precursor, or a mixture of low-k precursor insulating materials, may be introduced into a deposition chamber wherein it is exposed to a plasma. The exposure to the plasma induces oligomerization, or polymerization, of the low-k precursor material, or materials, to create a flowable liquid, or oligomer, of the low-k insulating material, or materials. The flowable liquid, or oligomer, can flow like a liquid into the high aspect ratio features. The flowability of the low-k insulating material in FCVD leads to less voids, breadloafing, or other defects, in the high aspect ratio surface features when compared to CVD.

Some low-k precursor insulating materials that have proven useful in depositing low-k insulating materials in high aspect ratio surface features via the FCVD process include trimethoxysiloxane (TRIMOS) triethoxysiloxane (TRIEOS), hexamethoxydisiloxane (HMODS), and octamethoxytrisiloxane (OMOTS). See, for example, U.S. Pat. No. 7,943,531. Other low-k precursor materials useful in FCVD include cyclosiloxanes, such as octamethylcyclotrisiloxane (OMTS), octamethylcyclotetrasiloxane (OMCTS), and 2,4,6-8-tetramethylcyclotetrasiloxane (TMCTS). See, for example, U.S. Pat. No. 7,825,038. While cyclosiloxane precursors work well in the FCVD process, they are not without issue. For example, TMCTS may oligomerize, or polymerize, before being exposed to the plasma during the FCVD process. Then, when exposed to the plasma, the oligomerized, or polymerized, TMCTS material may lose its ability to flow like a liquid into the high aspect ratio surface features during the FCVD process. Accordingly, a need exists for low-k cyclosiloxane precursor materials that exhibit less tendency to oligomerize, or polymerize, before being exposed to a plasma in the FCVD process.

The present disclosure is directed to overcoming on or more problems set forth above, and/or other problems associated with the prior art.

### SUMMARY OF THE INVENTION

In accordance with one aspect of the present disclosure, a composition is disclosed. This composition may comprise a compound represented by Formulas A, B, or C, below:

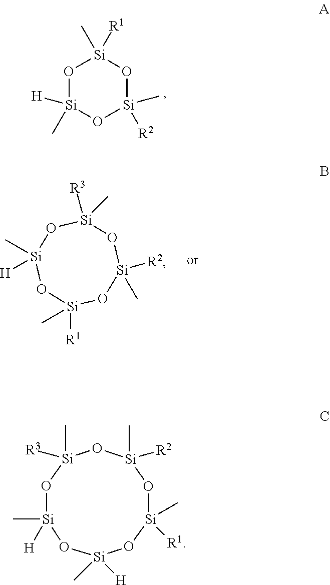

In each of the compounds represented above, R¹ is and alkoxy-group having 1 to 10 carbon atoms. R² may be H, or an alkoxy-group having 1 to 10 carbon atoms. Finally, R³, if present, may be H, or an alkoxy-group having 1 to 10 carbon atoms.

In one instance, R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this embodiment, R² is H, and R³ is also H.

In another instance, R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this particular embodiment, R² is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, cyclopentoxy, cyclohexoxy, and combinations thereof. In this embodiment, R³ is H.

In an additional instance, R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this embodiment R² is H, and R³ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof.

In another example, R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this last preferred embodiment, R² is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. Finally, in this embodiment, R³ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-2-butoxy, a cyclopentoxy, a cyclohexoxy, and combinations thereof.

In accordance with this aspect of the invention, the alkoxy-functionalized cyclosiloxane compound may be generally depicted by Formula A, and the alkoxy-functionalized cyclosiloxane compound may be selected from the group consisting of:

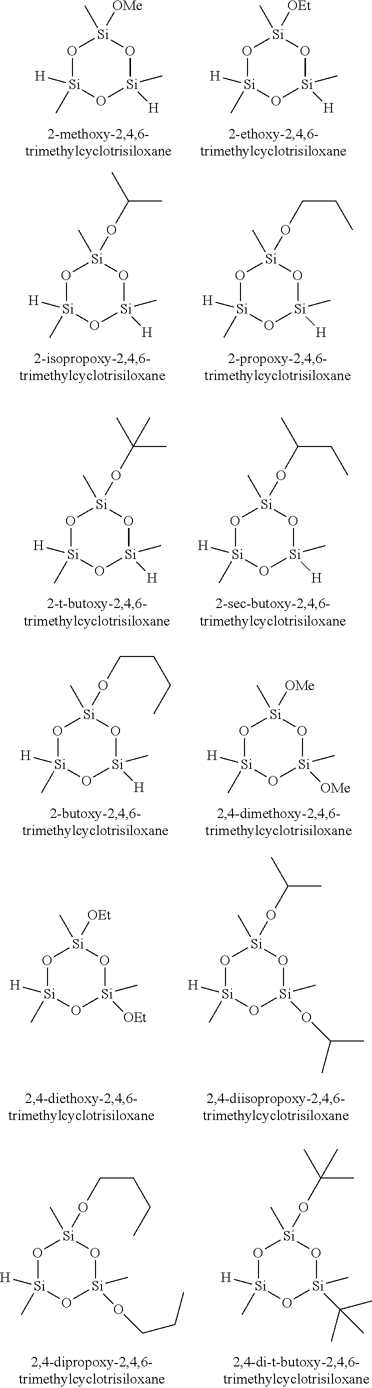

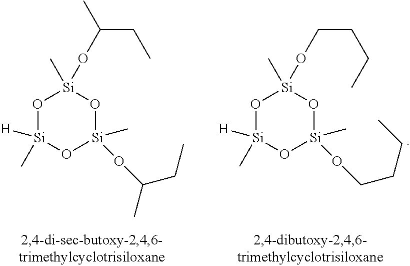

In accordance with this aspect of the invention, the alkoxy-functionalized cyclosiloxane compound may be generally depicted by Formula B, and the alkoxy-functionalized cyclosiloxane compound may be selected from the group consisting of:

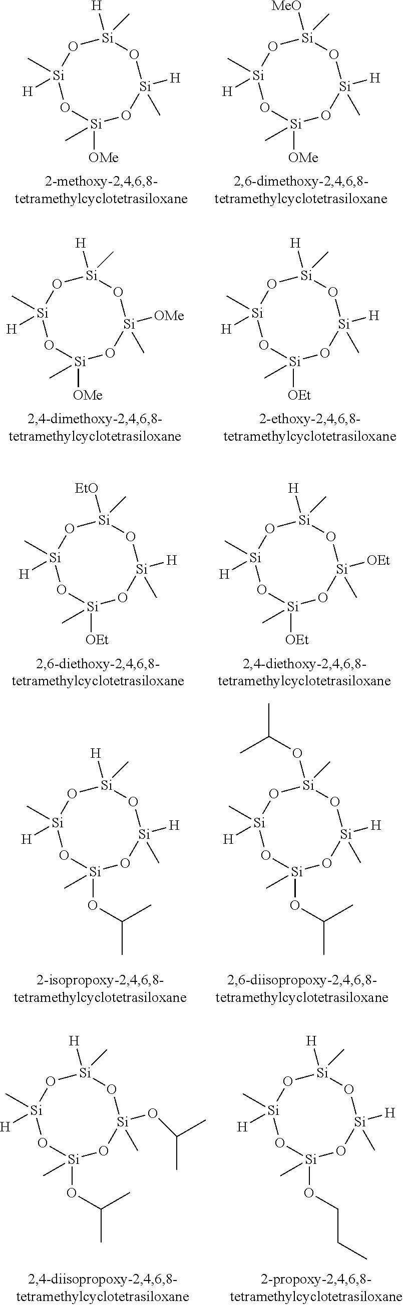

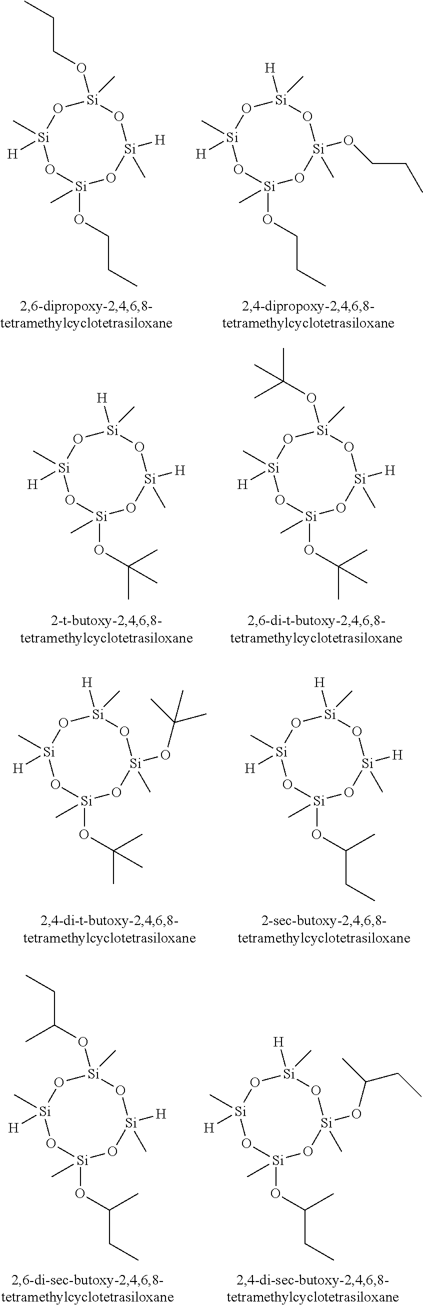

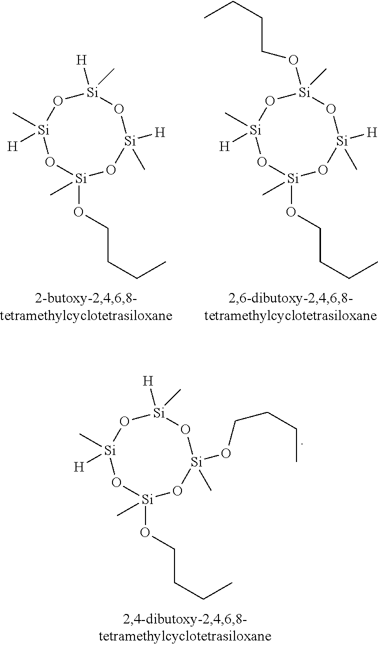 [SMILES: CCCCO[Si]1(C)O[SiH](C)O[SiH](C)O[SiH](C)O1 ; CCCCO[Si]1(C)O[SiH](C)O[Si](C)(OCCCC)O[SiH](C)O1 ; CCCCO[Si]1(C)O[SiH](C)O[SiH](C)O[Si](C)(OCCCC)O1]

In accordance with this aspect of the invention, the alkoxy-functionalized cyclosiloxane compound may be generally depicted by Formula C, and the alkoxy-functionalized cyclosiloxane compound may be selected from the group consisting of:

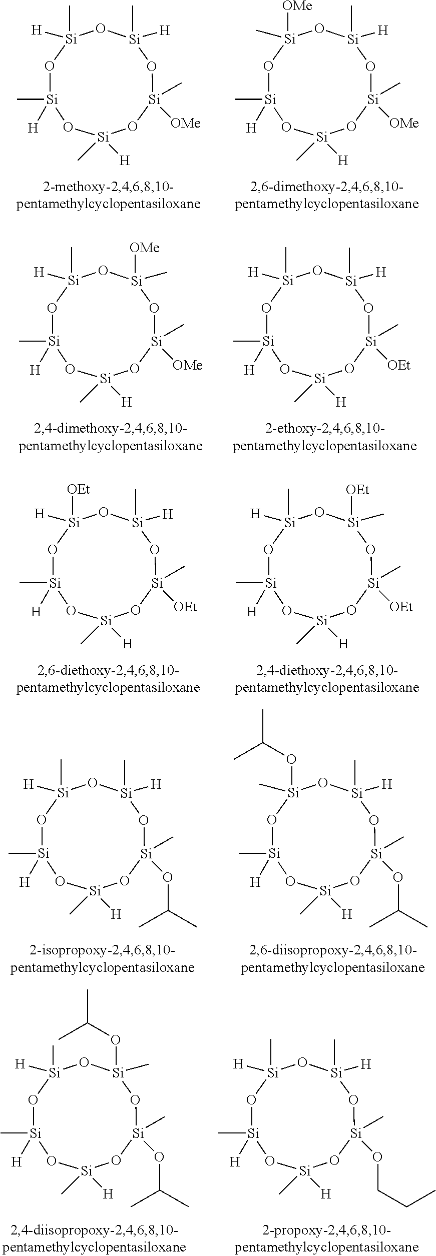

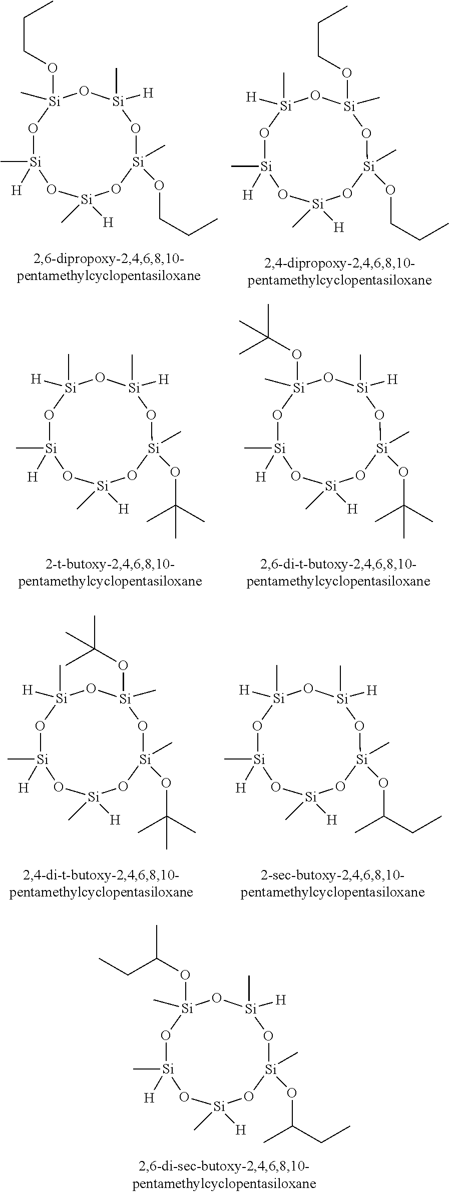

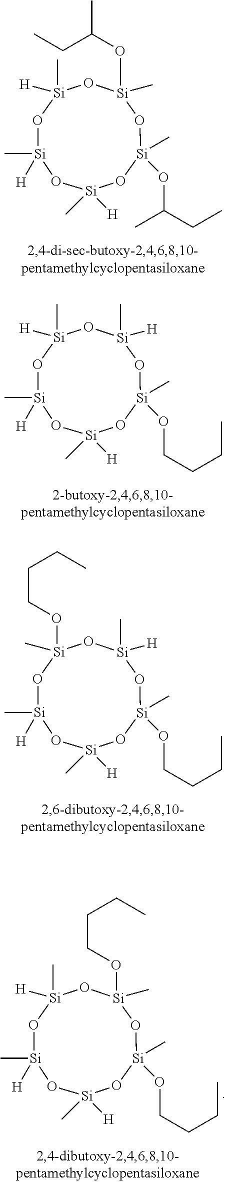

In accordance with this same aspect of the invention, the composition may comprise a mixture of these alkoxy-functionalized cyclosiloxane compounds. For example, the composition may comprise a mixture of compounds of Formula A and Formula B. In another instance, the mixture of compounds may comprise compounds of Formula A and Formula C. In an additional instance, the mixture of compounds may comprise compounds of Formula B and Formula C. Finally, the mixture of compounds may comprise compounds of Formula A, Formula B, and Formula C.

In accordance with a second aspect of the invention, a method of depositing a silicon-containing film is disclosed. The method may comprise the steps of placing a substrate comprising a surface feature into a deposition chamber of a CVD tool, such as a plasma-enhanced CVD tool (PECVD). The method may additionally comprise introducing two, or more, molecules of an alkoxy-functionalized cyclosiloxane compound represented by Formulas A, B, or C, below, into the deposition chamber:

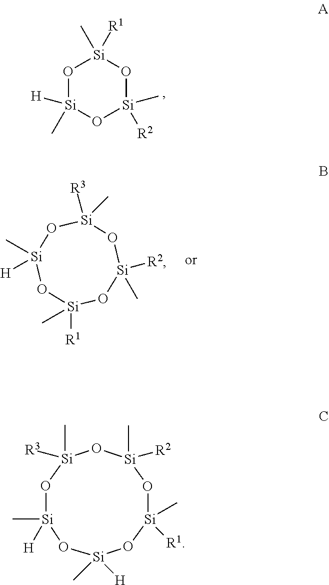

In each of the compounds represented above, R¹ is and alkoxy-group having 1 to 10 carbon atoms. R² may be H, or an alkoxy-group having 1 to 10 carbon atoms. Finally, R³, if present, may be H, or an alkoxy-group having 1 to 10 carbon atoms.

Then, the two, or more, molecules of the alkoxy-functionalized cyclosiloxane compound represented by Formulas A, B, or C, may be exposed to a plasma in the deposition chamber. This exposure to the plasma may induce a reaction between the two, or more, molecules, and thus create a flowable liquid, or oligomer, made from the two, or more, molecules of the alkoxy-functionalized cyclosiloxane compound represented by Formulas A, B, or C. This flowable liquid, or oligomer, may be permitted to at least partially fill the surface feature of the substrate and thus create the silicon-containing film.

In one embodiment, this method of depositing a silicon-containing film may also comprise wherein the introducing step further comprises introducing an inert gas into the deposition chamber, wherein the inert gas is selected from the group consisting of helium, argon, xenon, and mixtures thereof. The plasma in the exposing step may be an in-situ plasma, and the atoms of the inert gas may not be incorporated into the into the flowable liquid, or oligomer, made from the two, or more, molecules of the alkoxy-functionalized cyclosiloxane compound represented by the Formulas A, B or C, by exposure to the in-situ plasma in the deposition chamber, thereby creating a silicon-containing film comprising silicon and carbon.

In another embodiment of this method, the introducing step may further comprise introducing a nitrogen source into the deposition chamber, wherein the nitrogen source may be selected from the group consisting of N₂, ammonia, NF3, an organoamine, and mixtures thereof. In this embodiment, the plasma in the exposing step may be an in-situ plasma, and the nitrogen atoms of the nitrogen source may be incorporated into the flowable liquid, or oligomer, made from the two, or more, molecules of the alkoxy-functionalized cyclosiloxane compound represented by the Formulas A, B or C, by exposure to the in-situ plasma in the deposition chamber, thereby creating a silicon-containing film comprising silicon, carbon, and nitrogen.

In an additional embodiment of this method, the introducing step may further comprise introducing an oxygen source selected from the group consisting of water, oxygen, ozone, nitric oxide, nitrous oxide, carbon monoxide, carbon dioxide, and combinations thereof, and the plasma in the exposing step may be an in-situ plasma. In this embodiment, the oxygen atoms of the oxygen source may be incorporated into the flowable liquid, or oligomer, made from the two, or more, molecules of the alkoxy-functionalized cyclosiloxane compound represented by the Formulas A, B or C, by exposure to the in-situ plasma in the deposition chamber, thereby creating a silicon-containing film comprising silicon, carbon, and oxygen.

In another embodiment of this method, the plasma in the exposing step may be a remote plasma comprising an inert gas, and the inert gas may be selected from the group consisting of helium, argon, xenon, and mixtures thereof. In this embodiment the atoms of the inert gas may not be incorporated into the into the flowable liquid, or oligomer, made from the two, or more, molecules of the alkoxy-functionalized cyclosiloxane compound represented by the Formulas A, B or C, after exposure to the remote plasma in the deposition chamber, thereby creating a silicon-containing film comprising silicon and carbon.

This embodiment of the method described in this aspect of the invention may additionally include wherein the plasma in the exposing step may be a remote plasma comprising a nitrogen source, and the nitrogen source may be selected from the group consisting of N2, ammonia, NF3, an organoamine, and mixtures thereof. In this embodiment the nitrogen atoms of the nitrogen source may be incorporated into the flowable liquid, or oligomer, made from the two, or more, molecules of the alkoxy-functionalized cyclosiloxane compound represented by the Formulas A, B or C, after exposure to the remote plasma in the deposition chamber, thereby creating a silicon-containing film comprising silicon, carbon, and nitrogen.

This method in this second aspect of the invention may also include wherein the plasma in the exposing step is a remote plasma comprising an oxygen source. The oxygen source may selected from the group consisting of water, oxygen, ozone, nitric oxide, nitrous oxide, carbon monoxide, carbon dioxide, and combinations thereof. In this embodiment, oxygen atoms of the oxygen source may be incorporated into the flowable liquid, or oligomer, made from the two, or more, molecules of the alkoxy-functionalized cyclosiloxane compound represented by the Formulas A, B or C, after exposure to the remote plasma in the deposition chamber. In this instance a silicon-containing film comprising silicon, carbon, and oxygen may be created.

In this method, the substrate may be pre-treated in a pre-treatment step before placing it into the deposition chamber, and the pre-treatment step may selected from the group consisting of a plasma treatment, a thermal treatment, a chemical treatment, exposure to ultraviolet light, exposure to an electron beam, and combinations thereof.

This method may also comprise a post-treatment in a post-treatment step. The post-treatment may be selected from the group consisting of an ultraviolet cure of the silicon-containing film, a plasma annealing of the silicon-containing film, an infrared treatment of the silicon-containing film, a thermal annealing of the silicon-containing film in non-oxygenated environment, a thermal annealing of the silicon-containing film in an oxygenated environment, and combinations thereof, thereby densifying the silicon-containing film.

In accordance with a third aspect of the present disclosure, a film on a substrate is disclosed. The film may comprise a flowable liquid, or oligomer, comprising two, or more, oligomerized, or polymerized, molecules of an alkoxy-functionalized cyclosiloxane compound depicted by Formulas A, B, or C, below:

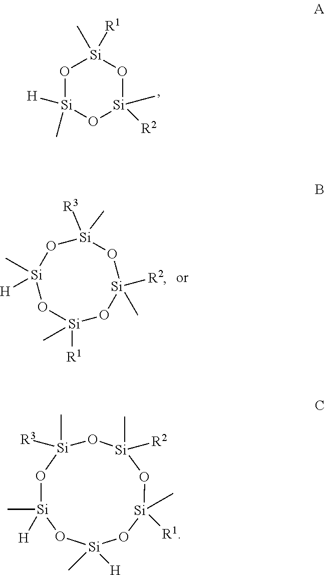

In each of the compounds represented above, R¹ is and alkoxy-group having 1 to 10 carbon atoms. R² may be H, or an alkoxy-group having 1 to 10 carbon atoms. Finally, R³, if present, may be H, or an alkoxy-group having 1 to 10 carbon atoms.

### BRIEF DESCRIPTION OF THE DRAWINGS

FIG. 1 is a SEM photograph of patterned wafers having a 2-ethoxy-2,4,6,8-tetramethylcyclotetrasiloxane silicon-containing film deposited in accordance with Working Example 21, which has the as deposited film thermally annealed in a non-oxygenated atmosphere, and then UV cured.

FIG. 2 is another SEM photograph of patterned wafers having a 2-ethoxy-2,4,6,8-tetramethylcyclotetrasiloxane silicon-containing films deposited in accordance with Working Example 21, which has the as deposited film thermally annealed in a non-oxygenated atmosphere, and UV cured.

FIG. 3 is an SEM photograph of a different sized pattern wafer having a 2-ethoxy-2,4,6,8-tetramethylcyclotetrasiloxane silicon containing-film deposited in accordance with Working Example 22, which has the as deposited film thermally annealed in an oxygenated atmosphere, and UV cured.

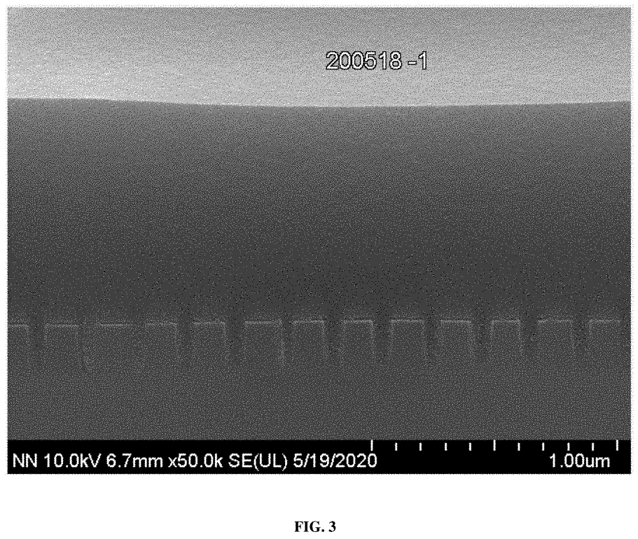

FIG. 4 is an SEM photograph of an as-deposited 2-isopropoxy-2,4,6,8-tetramethylcyclotetrasiloxane silicon containing-film deposited in accordance with Working Example 23, without thermal anneal, or UV cure.

FIG. 5 is an SEM photograph of an as-deposited 2-isopropoxy-2,4,6,8-tetramethylcyclotetrasiloxane silicon containing-film deposited in accordance with Working Example 23, which has the as deposited film thermally annealed in a non-oxygenated atmosphere, and UV cured.

FIG. 6 is a graph depicting the electrical breakdown of films created with 2-ethoxy-2,4,6,8-tetramethylcyclotetrasiloxane, versus the electrical breakdown of films created with 2-isopropoxy-2,4,6,8-tetramethylcyclotetrasiloxane.

### DETAILED DESCRIPTION

Various aspects of the disclosure will now be described with reference to the drawings and tables disclosed herein, if applicable, with like reference numbers referring to like elements, unless specified otherwise. As described above, while cyclosiloxane precursors work well in the FCVD process, they are not without issue. For example, TMCTS may oligomerize, or polymerize, before being exposed to a plasma in the FCVD process. Then, when exposed to the plasma, the oligomerized, or polymerized, TMCTS material may lose some of its ability to flow like a liquid into high aspect ratio surface features. As such, the Applicant researched means to reduce the potential of low-k cyclosiloxane precursor materials to oligomerize, or polymerize, before being exposed to the plasma in the FCVD process.

To this end, the Applicant studied cationic ring opening polymerization propagation reactions of TMCTS and 2-ethoxy-2,4,6,8-tetramethylcyclotetrasiloxane. As depicted below, the Applicant believes that TMCTS oligomerizes, or polymerizes, at least by the cationic ring opening sequence that follows:

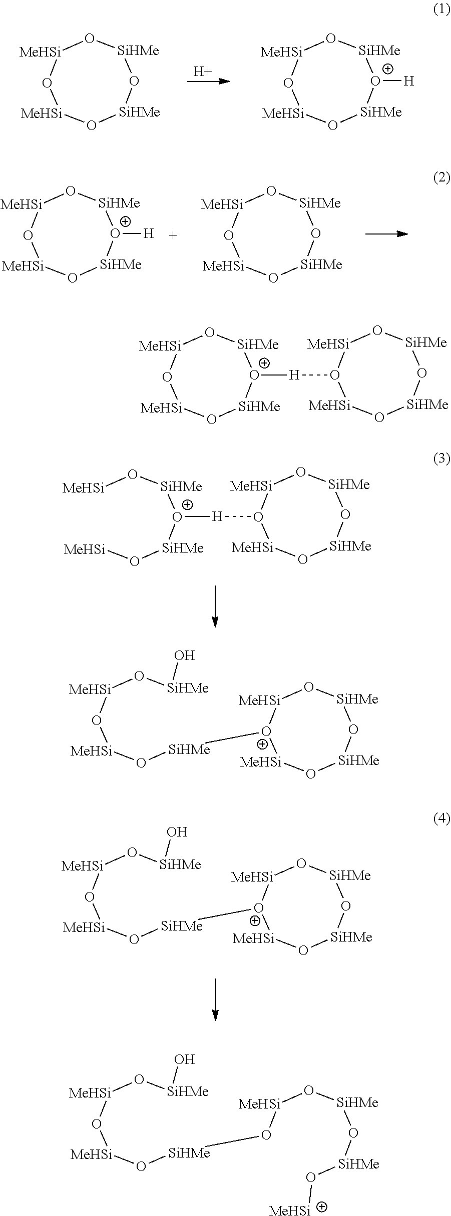

As depicted above in step (1) of the sequence, the Applicant believes that an oxygen atom of a first TMCTS molecule becomes protonated. Subsequently, in step (2) of the sequence, the first TMCTS molecule having a protonated oxygen atom is stabilized by coordination with an oxygen atom of a second TMCTS molecule. Charge transfer between the protonated oxygen atom of the first TMCTS molecule, and the coordinated oxygen atom of the second TMCTS occurs, thereby leading to a ring opening of the first TMCTS molecule, as is depicted in step (3) of the sequence above. Finally, in step (4) of the sequence illustrated above, charge transfer occurs within the second TMCTS molecule leading to ring opening of the second TMCTS molecule, thus creating a TMCTS oligomer, that may then further oligomerize with a nearby TMCTS molecule, and may eventually polymerize with additional TMCTS molecules. The Applicant believes that 2-ethoxy-2,4,6,8-tetramethylcyclotetrasiloxane goes through an analogous cationic ring opening sequence.

Surprisingly, the Applicant learned that 2-ethoxy-2,4,6,8-tetramethylcyclotetrasiloxane is more thermally stable than TMCTS by computer modeling the cationic ring opening sequences described above. As such, the Applicant believes that 2-ethoxy-2,4,6,8-tetramethylcyclotetrasiloxane is more thermally stable than TMCTS. As a consequence, the Applicant believes that functionalizing at least one silicon atom of a cyclosiloxane precursor material, like TMCTS, with an alkoxy-group leads to greater thermal stability of the precursor, thereby lessening any tendency for it to oligomerize, or polymerize, before being exposed to a plasma in the FCVD process, in comparison to TMCTS.

Accordingly, disclosed herein in a first aspect of the invention, are novel, and non-obvious, compositions comprising an alkoxy-functionalized cyclosiloxane compound useful as a precursor in FCVD processes. The compounds disclosed herein include those depicted by the Formulas A, B, or C, below:

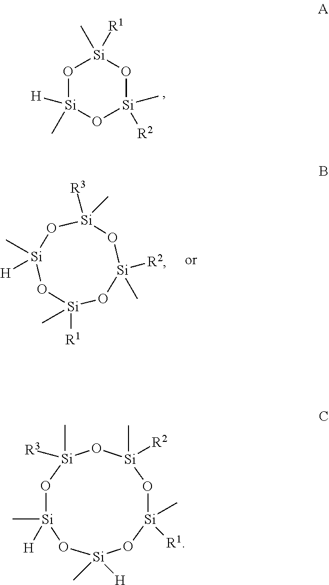

In each of the compounds represented above, R¹ is and alkoxy-group having 1 to 10 carbon atoms. R² may be H, or an alkoxy-group having 1 to 10 carbon atoms. Finally, R³, if present, may be H, or an alkoxy-group having 1 to 10 carbon atoms.

For sake of clarity, in the Formulas depicted above, and described throughout the description, the term “alkoxy-group” refers to an —OR group, wherein R comprises between 1 and 10 carbon atoms. As an example, in one embodiment, the alkoxy-group may be selected from the group consisting of a 1-heptyloxy, a 1-octyloxy, a 1-nonyloxy, and a 1-decyloxy. In a more preferred embodiment, the alkoxy-group is selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof.

Based on the description just above, in a preferred embodiment, a composition is disclosed comprising an alkoxy-functionalized cyclosiloxane compound depicted by Formulas A, B, or C above, wherein R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this embodiment, R² is H, and R³ is also H.

In an additional preferred embodiment, a composition is disclosed comprising an alkoxy-functionalized cyclosiloxane compound wherein R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this particular embodiment, R² is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, cyclopentoxy, cyclohexoxy, and combinations thereof. In this preferred embodiment, R³ is H.

In another preferred embodiment, a composition is disclosed comprising an alkoxy-functionalized cyclosiloxane compound wherein R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this preferred embodiment R² is H, and R³ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof.

In a last preferred embodiment, a composition is disclosed comprising an alkoxy-functionalized cyclosiloxane compound wherein R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this last preferred embodiment, R² is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. Finally, in this embodiment, R³ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof.

Moving on, in a more preferred embodiment of this aspect of the invention, a composition is disclosed wherein the alkoxy-functionalized cyclosiloxane compound is generally depicted by Formula A, and this alkoxy-functionalized cyclosiloxane compound is selected from the group consisting of:

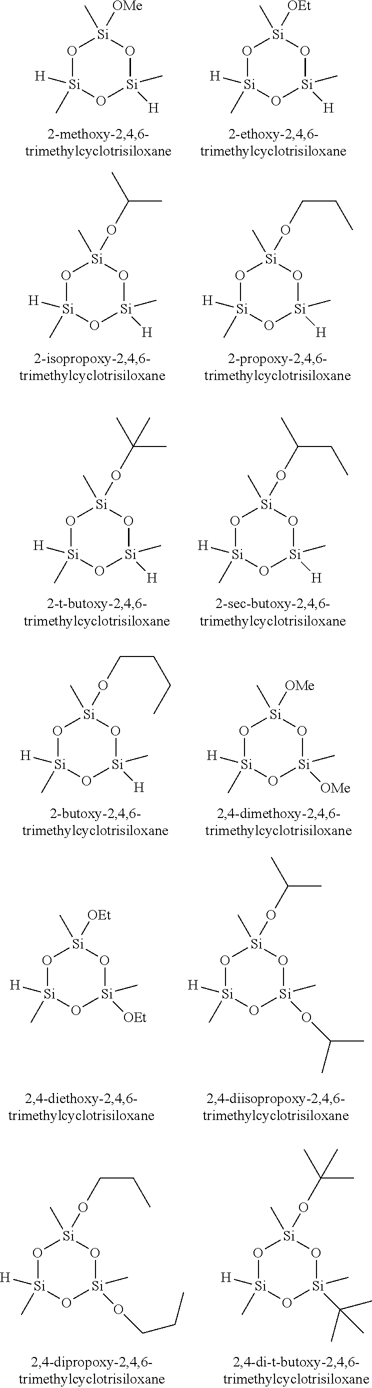

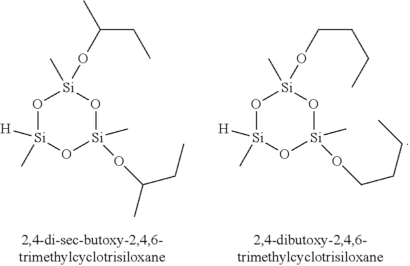

In another more preferred embodiment of this aspect of the invention, a composition is disclosed wherein the alkoxy-functionalized cyclosiloxane compound is generally depicted by Formula B, and this alkoxy-functionalized cyclosiloxane compound is selected from the group consisting of:

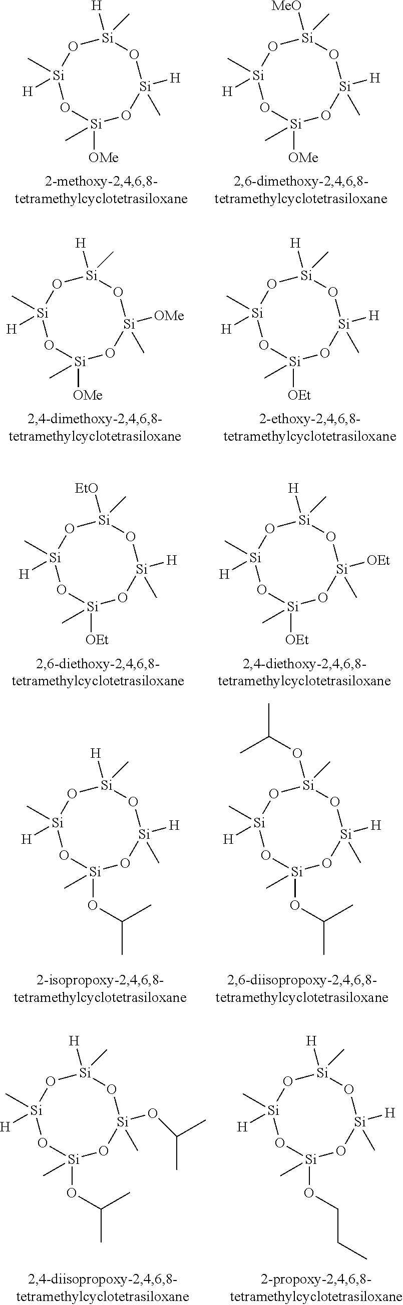

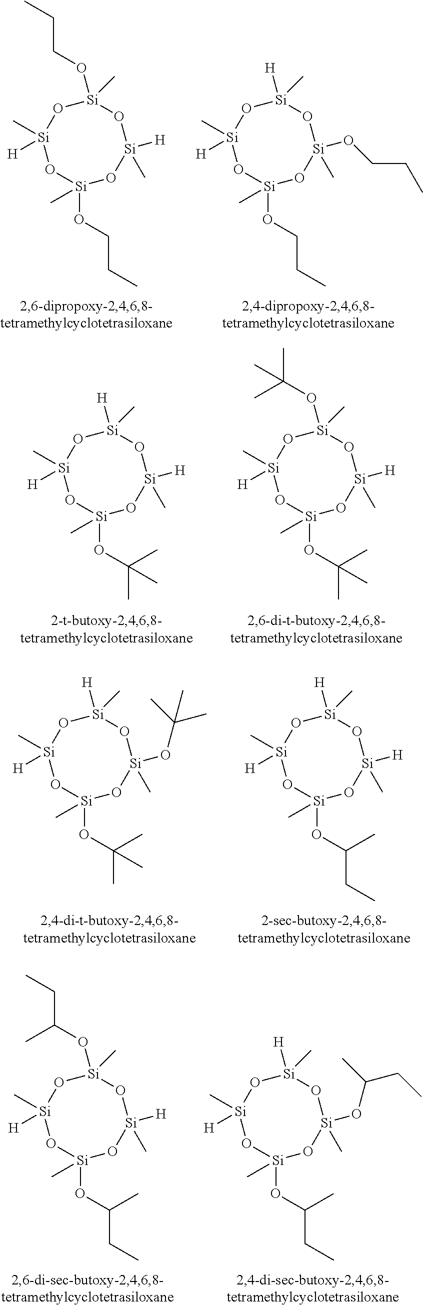

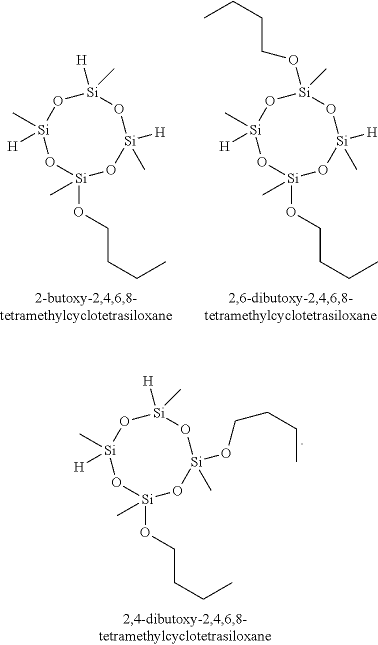 [SMILES: CCCCO[Si]1(C)O[SiH](C)O[SiH](C)O[SiH](C)O1 ; CCCCO[Si]1(C)O[SiH](C)O[Si](C)(OCCCC)O[SiH](C)O1 ; CCCCO[Si]1(C)O[SiH](C)O[SiH](C)O[Si](C)(OCCCC)O1]

Finally, in an additional more preferred embodiment of this aspect of the invention, a composition is disclosed wherein the alkoxy-functionalized cyclosiloxane compound is generally depicted by Formula C, and this alkoxy-functionalized cyclosiloxane compound is selected from the group consisting of:

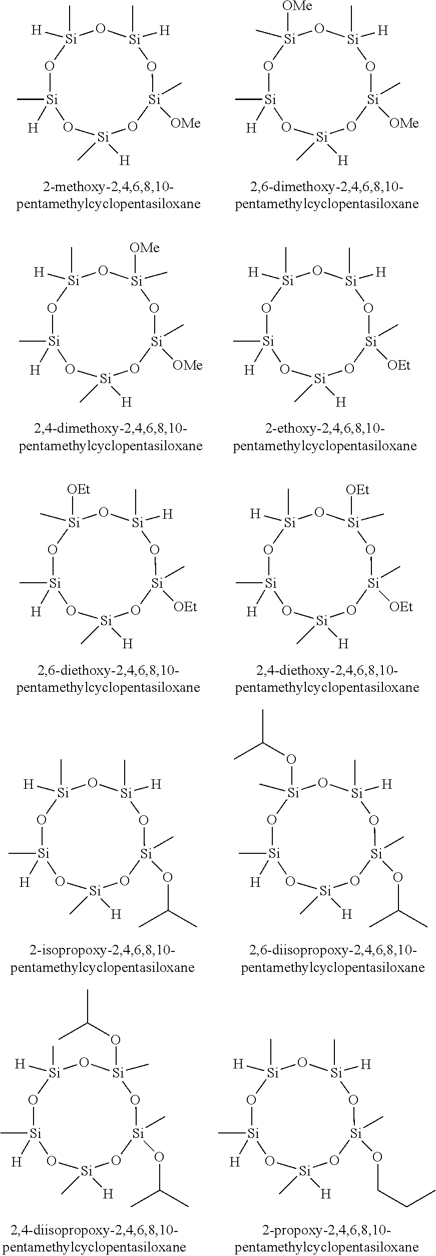

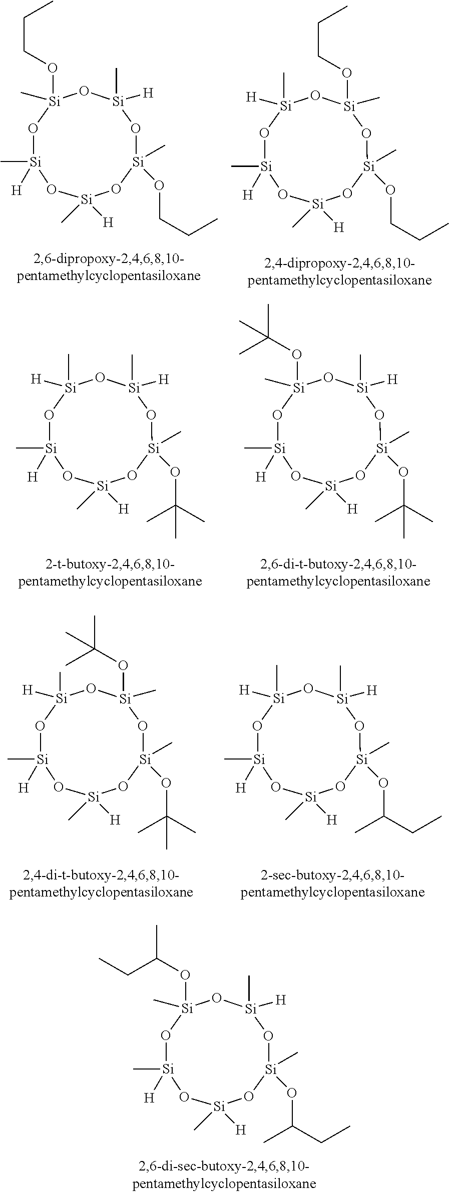

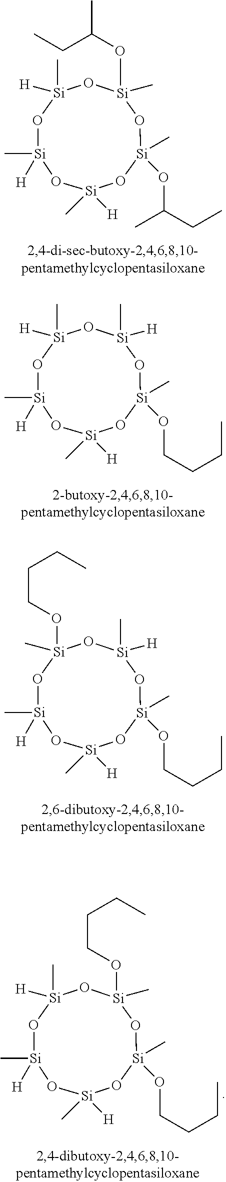

The Applicant envisions that in some instances a composition comprising a mixture of alkoxy-functionalized cyclosiloxane compounds depicted by Formulas A, B or C, may be preferable to a composition comprising only one of the alkoxy-functionalized cyclosiloxane compounds depicted by Formulas A, B, or C. A mixture of these alkoxy-functionalized cyclosiloxane compounds may, for example, comprise a mixture of compounds of Formula A and Formula B. In another instance, the mixture of compounds may comprise compounds of Formula A and Formula C. In an additional instance, the mixture of compounds may comprise compounds of Formula B and Formula C. Finally, the mixture of compounds may comprise compounds of Formula A, Formula B, and Formula C.

Moving on, the alkoxy-functionalized cyclosiloxane compounds having Formulas A, B, or C depicted or described above may be produced, for example, by the reaction between a cyclosiloxane and an alcohol. In this reaction, a hydrogen atom attached to a silicon atom of the cyclosiloxane may be substituted with an alkoxy-group corresponding to the alcohol having between 1 and 10 carbon atoms utilized in the reaction. In some embodiments a catalyst may be utilized to increase the rate at which this reaction occurs. In certain embodiments, this reaction takes place in a mixture of the cyclosiloxane, the alcohol of interest, and additionally in the presence of a catalyst as a solution in a solvent. While not intending to be limiting, the cyclosiloxane reactants may include 2,4,6-trimethylcyclotrisiloxane (TRIMCTS), 2,4,6,8-tetramethylcyclotetrasiloxane (TMCTS), and 2,4,6,8,10-pentamethylcyclopentasiloxane (PMCPS), as is demonstrated above. While not depicted in this application, other cyclosiloxane reactants (e.g., 2,4,6,8,10,12-hexamethylcyclohexasiloxane) are certainly within the scope of this disclosure.

The alcohol reactant has between 1 and 10 carbon atoms. In certain embodiments, the alcohol is selected from the group consisting of 1-heptanol, 1-octanol, 1-nonanol, and 1-decanol. In preferred embodiments of this aspect of the disclosure, the alcohol comprises between 1 and 6 carbon atoms, and the alcohol is selected from the group consisting of methanol, ethanol, 1-propanol, isopropanol, 1-butanol, tert-butanol, sec-butanol, 1-pentanol, 2-pentanol, 3-pentanol, 2-methyl-1-butanol, 3-methyl-1-butanol, 2-methyl-2-butanol, 2-methyl-3-butanol, 2,2-dimethyl-1-propanol, 1-hexanol, 2-hexanol, 3-hexanol, 2-methyl-1-pentanol, 3-methyl-1-pentanol, 4-methyl-1-pentanol, 2-methyl-2-pentanol, 3-methyl-2-pentanol, 4-methyl-2-pentanol, 2-methyl-3-pentanol, 3-methyl-3-pentanol, 2,2-dimethyl-1-butanol, 2,3-dimethyl-1-butanol, 2,3-dimethyl-2-butanol, 3,3,-dimethyl-2-butanol, 2-ethyl-1-butanol, cyclopentanol, cyclohexanol, and combinations thereof.

The catalyst employed in the method of making alkoxy-functionalized cyclosiloxanes disclosed herein is one that promotes the formation of a silicon-oxygen bond. Exemplary catalysts that may be utilized with the method disclosed herein include, but are not limited to, halide-free main group, transition metal, lanthanide, and actinide catalysts, such as the following: 1,3-di-iso-propyl-4,5-dimethylimidazol-2-ylidene, 2,2′-bipyridyl, phenanthroline, B(C₆F₅)₃, BR₃ (R=linear, branched, or cyclic C₁ to C₁₀ alkyl group, a C₅ to C₁₀ aryl group, or a C₁ to C₁₀ alkoxy group), AlR₃ (R=linear, branched, or cyclic C₁ to C₁₀ alkyl group, a C₅ to C₁₀ aryl group, or a C₁ to C₁₀ alkoxy group), (C₅H₅)₂TiR₂ (R=alkyl, H, alkoxy, organoamino, carbosilyl), (C₅H₅)₂Ti(OAr)₂ [Ar=(2,6-(ⁱPr)₂C₆H₃)], (C₅H₅)₂Ti(SiHRR′)PMe₃ (wherein R, R′ are each independently selected from H, Me, Ph), TiMe₂(dmpe)₂ (dmpe=1,2-bis(dimethylphosphino)ethane), bis(benzene)chromium(O), Cr(CO)₆, Mn₂(CO)₁₂, Fe(CO)₅, Fe₃(CO)₁₂, (C₅H₅)Fe(CO)₂Me, Co₂(CO)₈, Ni(II) acetate, Nickel(II) acetylacetonate, Ni(cyclooctadiene)₂, [(dippe)Ni(μ-H)]2 (dippe=1,2-bis(di-iso-propylphosphino)ethane), (R-indenyl)Ni(PR′₃)Me (R=1-ⁱPr, 1-SiMe₃, 1,3-(SiMe₃)₂; R′=Me, Ph), [{Ni(η-CH₂:CHSiMe₂)₂O}₂{μ-(η-CH₂:CHSiMe₂)₂O}], Cu(I) acetate, CuH, [tris(4,4-dimethyl-2-oxazolinyl)phenylborate]ZnH, (C₅H₅)₂ZrR₂(R=alkyl, H, alkoxy, organoamino, carbosilyl), Ru₃(CO)₁₂, [(Et₃P)Ru(2,6-dimesitylthiophenolate)][B[3,5-(CF₃)₂C₆H₃]₄], [(C₅Me₅)Ru(R₃P)×(NCMe)₃₋ₓ]⁺ (wherein R is selected from a linear, branched, or cyclic C₁ to C₁₀ alkyl group and a C₅ to C₁₀ aryl group; x=0, 1, 2, 3), Rh₆(CO)₁₆, tris(triphenylphosphine)rhodium(I)carbonyl hydride, Rh₂H₂(CO)₂(dppm)₂ (dppm=bis(diphenylphosphino)methane, Rh₂(μ-SiRH)₂(CO)₂(dppm)₂ (R=Ph, Et, C₆H₁₃), Pd/C, tris(dibenzylideneacetone)dipalladium(0), tetrakis(triphenylphosphine)palladium(0), Pd(II) acetate, (C₅H₅)₂SmH, (C₅Me₅)₂SmH, (THF)₂Yb[N(SiMe₃)₂]₂, (NHC)Yb(N(SiMe₃)₂)₂ [NHC=1,3-bis(2,4,6-trimethylphenyl) imidazol-2-ylidene)], Yb(η²-Ph₂CNPh)(hmpa)₃ (hmpa=hexamethylphosphoramide), W(CO)₆, Re₂(CO)₁₀, Os₃(CO)₁₂, Ir₄(CO)₁₂, (acetylacetonato)dicarbonyliridium(I), Ir(Me)₂(C₅Me₅)L (L=PMe₃, PPh₃), [Ir(cyclooctadiene)OMe]₂, PtO₂ (Adams's catalyst),), platinum on carbon (Pt/C), ruthenium on carbon (Ru/C), ruthenium on alumina, palladium on carbon, nickel on carbon, osmium on carbon, Platinum(0)-1,3-divinyl-1,1,3,3-tetramethyldisiloxane (Karstedt's catalyst), bis(tri-tert-butylphosphine)platinum(0), Pt(cyclooctadiene)₂, [(Me₃Si)₂N]₃U][BPh₄], [(Et₂N)₃U][BPh₄], and other halide-free Mⁿ⁺ complexes (M=Sc, Ti, V, Cr, Mn, Fe, Co, Ni, Cu, Zn, Y, Zr, Nb, Mo, Ru, Rh, Pd, La, Ce, Pr, Nd, Pm, Sm, Eu, Gd, Tb, Dy, Ho, Er, Tm, Yb, Lu, Hf, Ta, W, Re, Os, Ir, Pt, U; n=0, 1, 2, 3, 4, 5, 6).

The catalysts listed above, as well as pure noble metals such as ruthenium platinum, palladium, rhodium, osmium, may also be affixed to a support. The support may be a solid with a high surface area. Typical support materials include but are not limited to: alumina, MgO, zeolites, carbon, Monolith cordierite, diatomaceous earth, silica gel, silica/alumina, ZrO, TiO₂, and metal-organic frameworks (MOF). Preferred supports are carbon (e.g., platinum on carbon, palladium on carbon, rhodium on carbon, ruthenium on carbon) alumina, silica and MgO. Metal loading of the catalyst ranges between about 0.01 weight percent to about 50 weight percent. A preferred range is about 0.5 weight percent to about 20 weight percent. A more preferred range is about 0.5 weight percent to about 10 weight percent. Catalysts requiring activation may be activated by a number of known methods. Heating the catalyst under vacuum is a preferred method. The catalyst may be activated before addition to the reaction vessel or in the reaction vessel prior adding the reactants. The catalyst may contain a promoter. Promoters are substances which themselves are not catalysts, but when mixed in small quantities with the active catalysts increase their efficiency (activity and/or selectivity). Promoters are usually metals such as Mn, Ce, Mo, Li, Re, Ga, Cu, Ru, Pd, Rh, Ir, Fe, Ni, Pt, Cr, Cu and Au and/or their oxides. They can be added separately to the reactor vessel or they can be part of the catalysts themselves. For example, Ru/Mn/C (ruthenium on carbon promoted by manganese) or Pt/CeO₂/Ir/SiO₂(Platinum on silica promoted by ceria and iridium). Some promoters can act as catalyst by themselves but their use in combination with the main catalyst can improve the main catalyst's activity. A catalyst may act as a promoter for other catalysts. In this context, the catalyst can be called a bimetallic (or polymetallic) catalyst. For example, Ru/Rh/C can be called either ruthenium and rhodium on carbon bimetallic catalyst or ruthenium on carbon promoted by rhodium. An active catalyst is a material that acts as a catalyst in a specific chemical reaction.

The molar ratio of catalyst to cyclosiloxane in the reaction mixture ranges from 0.1 to 1, 0.05 to 1, 0.01 to 1, 0.005 to 1, 0.001 to 1, 0.0005 to 1, 0.0001 to 1, 0.00005 to 1, or 0.00001 to 1.

In some embodiments, the reaction mixture comprising the cyclosiloxane, alcohol(s), and catalyst(s) may additionally comprise an anhydrous solvent. Exemplary solvents may include, but are not limited to linear-, branched-, cyclic- or poly-ethers (e.g., tetrahydrofuran (THF), diethyl ether, diglyme, and/or tetraglyme); linear-, branched-, or cyclic-alkanes, alkenes, aromatics and halocarbons (e.g. pentane, hexanes, toluene and dichloromethane). The selection of one or more solvent, if added, may be influenced by its compatibility with reagents contained within the reaction mixture, the solubility of the catalyst, and/or the separation process for the intermediate product and/or the end product chosen. In other embodiments, the reaction mixture does not comprise a solvent.

In the reaction described herein, the reaction between the cyclosiloxane and the alcohol occurs at one or more temperatures ranging from about 0° C. to about 200° C., preferably 0° C. to about 100° C. Exemplary temperatures for the reaction include ranges having any one or more of the following endpoints: 0, 10, 20, 30, 40, 50, 60, 70, 80, 90, or 100° C. The suitable temperature range for this reaction may be dictated by the physical properties of the reagent, and optional solvent.

Examples of particular reaction temperature ranges include, but are not limited to, 0° C. to 80° C., or from 0° C. to 30° C.

In certain embodiments of the reaction described herein, the pressure of the reaction may range from about 1 to about 115 psia or from about 15 to about 45 psia. In some embodiments where the cyclosiloxane is a liquid under ambient conditions, the reaction is run at atmospheric pressure. In some embodiments where the cyclosiloxane is a gas under ambient conditions, the reaction is run above 15 psia.

In certain embodiments, one or more reagents may be introduced to the reaction mixture as a liquid or a vapor. In embodiments where one or more of the reactants is added as a vapor, a non-reactive gas such as nitrogen, or an inert gas, may be employed as a carrier gas to deliver the vapor to the reaction mixture. In embodiments where one or more of the reagents is added as a liquid, the reagent may be added neat, or may alternatively be diluted with a solvent.

The crude mixture comprising the alkoxy-functionalized cyclosiloxane compound of Formula A, B, or C, catalyst(s), and potentially residual cyclosiloxane, alcohol, and solvent(s), may require separation process(es). Examples of suitable separation processes include, but are not limited to, distillation, evaporation, membrane separation, filtration, vapor phase transfer, extraction, fractional distillation using an inverted column, and combinations thereof.

### Synthesis of Alkoxy-Functionalized Cyclosiloxanes

### Working Example 1—Synthesis of 2-methoxy-2,4,6,8-tetramethylcyclotetrasiloxane

To 1 mL of 2,4,6,8-tetramethylcyclotetrasiloxane in a 4 mL vial was added 0.25 mL of methanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=270 (M+), 255 (M−15), 239, 225, 209, 193, 179, 165, 148, 135, 119, 105, 89, 75, 59,

### Working Example 2—Synthesis of 2-ethoxy-2,4,6,8-tetramethylcyclotetrasiloxane

To 1 mL of 2,4,6,8-tetramethylcyclotetrasiloxane in a 4 mL vial was added 0.25 mL of ethanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=284 (M+), 269 (M−15), 253, 239, 223, 209, 193, 179, 165, 149, 135, 119, 105, 89, 73, 59,

### Working Example 3—Synthesis of 2-n-propoxy-2,4,6,8-tetramethylcyclotetrasiloxane

To 1 mL of 2,4,6,8-tetramethylcyclotetrasiloxane in a 4 mL vial was added 0.25 mL of 1-propanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=298 (M+), 283 (M−15), 269, 253, 239, 223, 209, 193, 179, 165, 149, 135, 119, 103, 89, 75, 59, 43.

### Working Example 4—Synthesis of 2-iso-propoxy-2,4,6,8-tetramethylcyclotetrasiloxane

To 1 mL of 2,4,6,8-tetramethylcyclotetrasiloxane in a 4 mL vial was added 0.25 mL of 2-propanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=298 (M+), 283 (M−15), 253, 239, 223, 209, 193, 179, 165, 149, 135, 119, 103, 89, 73, 59, 43.

### Working Example 5—Synthesis of 2-n-butoxy-2,4,6,8-tetramethylcyclotetrasiloxane

To 1 mL of 2,4,6,8-tetramethylcyclotetrasiloxane in a 4 mL vial was added 0.25 mL of 1-butanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=312 (M+), 297 (M−15), 269, 253, 239, 223, 209, 193, 179, 165, 149, 135, 119, 105, 89, 75, 57, 41.

### Working Example 6—Synthesis of 2-sec-butoxy-2,4,6,8-tetramethylcyclotetrasiloxane

To 1 mL of 2,4,6,8-tetramethylcyclotetrasiloxane in a 4 mL vial was added 0.25 mL of 2-butanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=312 (M+), 297 (M−15), 283, 253, 239, 223, 209, 193, 179, 165, 149, 135, 119, 104, 89, 75, 57, 41.

### Working Example 7—Synthesis of 2-tert-butoxy-2,4,6,8-tetramethylcyclotetrasiloxane

To 1 mL of 2,4,6,8-tetramethylcyclotetrasiloxane in a 4 mL vial was added 0.25 mL of t-butanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=312 (M+), 297 (M−15), 253, 239, 223, 209, 193, 179, 165, 149, 135, 119, 104, 89, 75, 57, 43.

### Working Example 8—Synthesis of 2-tert-pentoxy-2,4,6,8-tetramethylcyclotetrasiloxane

To 1 mL of 2,4,6,8-tetramethylcyclotetrasiloxane in a 4 mL vial was added 0.25 mL of t-amyl alcohol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=326 (M+), 311 (M−15), 297, 253, 239, 223, 209, 193, 179, 165, 149, 135, 119, 105, 89, 71, 57, 43.

### Working Example 9—Synthesis of 2-cyclopentoxy-2,4,6,8-tetramethylcyclotetrasiloxane

To 1 mL of 2,4,6,8-tetramethylcyclotetrasiloxane in a 4 mL vial was added 0.25 mL of cyclopentanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=324 (M+), 309 (M−15), 295, 281, 253, 239, 223, 209, 193, 179, 165, 148, 135, 119, 105, 89, 69, 55, 41.

### Working Example 10—Synthesis of 2-cyclohexoxy-2,4,6,8-tetramethylcyclotetrasiloxane

To 1 mL of 2,4,6,8-tetramethylcyclotetrasiloxane in a 4 mL vial was added 0.25 mL of cyclohexanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=338 (M+), 323 (M−15), 309, 295, 281, 253, 239, 223, 209, 193, 179, 165, 149, 135, 119, 103, 83, 69, 55, 41.

### Working Example 11—Synthesis of 2,4-dimethoxy-2,4,6,8-tetramethylcyclotetrasiloxane, or 2,6-dimethoxy-2,4,6,8-tetramethylcyclotetrasiloxane

To 1 mL of 2,4,6,8-tetramethylcyclotetrasiloxane in a 4 mL vial was added 0.25 mL of methanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=300 (M+), 285 (M−15), 269, 253, 239, 225, 209, 193, 179, 165, 149, 133, 119, 105, 89, 73, 59, 45.

### Working Example 12—Synthesis of 2,4-diethoxy-2,4,6,8-tetramethylcyclotetrasiloxane, or 2,6-diethoxy-2,4,6,8-tetramethylcyclotetrasiloxane

To 1 mL of 2,4,6,8-tetramethylcyclotetrasiloxane in a 4 mL vial was added 0.25 mL of ethanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=328 (M+), 313 (M−15), 297, 283, 269, 255, 239, 222, 208, 193, 179, 164, 148, 135, 119, 103, 89, 75, 59, 45.

### Working Example 13—Synthesis of 2,4-di-n-propoxy-2,4,6,8-tetramethylcyclotetrasiloxane, or 2,6-di-n-propoxy-2,4,6,8-tetramethylcyclotetrasiloxane

To 1 mL of 2,4,6,8-tetramethylcyclotetrasiloxane in a 4 mL vial was added 0.25 mL of 1-propanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=356 (M+), 341 (M−15), 327, 311, 297, 283, 269, 253, 239, 223, 209, 193, 179, 165, 149, 134, 119, 104, 89, 75, 59, 43.

### Working Example 14—Synthesis of 2,4-di-iso-propoxy-2,4,6,8-tetramethylcyclotetrasiloxane, or 2,6-di-iso-propoxy-2,4,6,8-tetramethylcyclotetrasiloxane

To 1 mL of 2,4,6,8-tetramethylcyclotetrasiloxane in a 4 mL vial was added 0.25 mL of 2-propanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=356 (M+), 341 (M−15), 326, 311, 299, 283, 269, 253, 239, 223, 209, 193, 179, 165, 149, 135, 119, 103, 89, 75, 59, 43.

### Working Example 15—Synthesis of 2,4-di-n-butoxy-2,4,6,8-tetramethylcyclotetrasiloxane, or 2,6-di-n-butoxy-2,4,6,8-tetramethylcyclotetrasiloxane

To 1 mL of 2,4,6,8-tetramethylcyclotetrasiloxane in a 4 mL vial was added 0.25 mL of 1-butanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=384 (M+), 369 (M−15), 353, 341, 325, 311, 297, 283, 269, 253, 239, 223, 209, 193, 179, 165, 149, 134, 119, 104, 89, 75, 57, 41.

### Working Example 16—Synthesis of 2,4-di-sec-butoxy-2,4,6,8-tetramethylcyclotetrasiloxane, or 2,6-di-sec-butoxy-2,4,6,8-tetramethylcyclotetrasiloxane

To 1 mL of 2,4,6,8-tetramethylcyclotetrasiloxane in a 4 mL vial was added 0.25 mL of 2-butanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=384 (M+), 369 (M−15), 355, 343, 325, 313, 299, 283, 269, 253, 239, 223, 209, 193, 179, 165, 149, 135, 119, 104, 89, 75, 57, 41.

### Working Example 17—Synthesis of 2,4-di-tert-butoxy-2,4,6,8-tetramethylcyclotetrasiloxane, or 2,6-di-tert-butoxy-2,4,6,8-tetramethylcyclotetrasiloxane

To 1 mL of 2,4,6,8-tetramethylcyclotetrasiloxane in a 4 mL vial was added 0.25 mL of t-butanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=384 (M+), 369 (M−15), 354, 343, 327, 313, 297, 281, 269, 253, 239, 223, 209, 193, 179, 165, 148, 135, 119, 103, 89, 75, 57, 41.

### Working Example 18—Synthesis of 2,4-di-tert-pentoxy-2,4,6,8-tetramethylcyclotetrasiloxane, or 2,6-di-tert-pentoxy-2,4,6,8-tetramethylcyclotetrasiloxane

To 1 mL of 2,4,6,8-tetramethylcyclotetrasiloxane in a 4 mL vial was added 0.25 mL of t-amyl alcohol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=412 (M+), 397 (M−15), 383, 367, 341, 327, 313, 297, 283, 269, 253, 239, 223, 209, 193, 179, 165, 148, 135, 119, 104,89, 71, 57, 43

### Working Example 19—Synthesis of 2,4-di-cyclopentoxy-2,4,6,8-tetramethylcyclotetrasiloxane, or 2,6-di-cyclopentoxy-2,4,6,8-tetramethylcyclotetrasiloxane

To 1 mL of 2,4,6,8-tetramethylcyclotetrasiloxane in a 4 mL vial was added 0.25 mL of cyclopentanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=408 (M+), 393 (M−15), 380, 365, 339, 325, 309, 297, 283, 269, 253, 239, 223, 209, 193, 179, 165, 147, 126, 111, 95, 69, 55, 41.

### Working Example 20—Synthesis of 2,4-di-cyclohexoxy-2,4,6,8-tetramethylcyclotetrasiloxane, or 2,6-di-cyclohexoxy-2,4,6,8-tetramethylcyclotetrasiloxane

To 1 mL of 2,4,6,8-tetramethylcyclotetrasiloxane in a 4 mL vial was added 0.25 mL of cyclohexanol directly, followed by a catalytic amount of Ru₃(CO)₁₂ as a solution in THF. The reaction mixture was left to sit for the extent of 16 hours, after which a sample was taken and run GC-MS confirming the formation of the desired product. GC-MS showed the following peaks: m/z=436 (M+), 421 (M−15), 407, 393, 379, 353, 339, 323, 309, 283, 269, 253, 239, 223, 209, 193, 179, 165, 147, 126, 111, 97, 83, 69, 55, 41.

### INDUSTRIAL APPLICABILITY

In operation, the alkoxy-functionalized cyclosiloxanes described and depicted above find applicability in many industrial applications including, but not limited to, their use as an insulating material deposited in high aspect ratio gaps, trenches, vias, and other surface features, between adjacent semiconductor devices. Accordingly, in a second aspect of the invention disclosed herein, a method of depositing a silicon-containing film with the alkoxy-functionalized cyclosiloxanes described and depicted above is disclosed. In this method, a substrate comprising a surface feature may be placed into a deposition chamber of a CVD tool, such as a PECVD tool.

In a particular embodiment of this aspect of the invention, the surface feature(s) have a width of 100 μm or less, 1 μm in width or less, or 0.5 μm in width. In this or other embodiments, the aspect ratio (the depth to width ratio) of the surface features, if present, is 0.1:1 or greater, or 1:1 or greater, or 10:1 or greater, or 20:1 or greater, or 40:1 or greater.

The substrate may be a single crystal silicon wafer, a wafer of silicon carbide, a wafer of aluminum oxide (sapphire), a sheet of glass, a metallic foil, an organic polymer film or may be a polymeric, glass, silicon or metallic 3-dimensional article. The substrate may be coated with a variety of materials well known in the art including films of silicon oxide, silicon nitride, amorphous carbon, silicon oxycarbide, silicon oxynitride, silicon carbide, gallium arsenide, gallium nitride and the like. These coatings may completely coat the substrate, may be in multiple layers of various materials and may be partially etched to expose underlying layers of material. The surface may also have on it a photoresist material that has been exposed with a pattern and developed to partially coat the substrate.

The temperature of the substrate may be controlled to be less than the walls of the deposition chamber. The substrate temperature is held at a temperature below 100° C., preferably at a temperature below 80° C., and most preferably below 60° C., and greater than −30° C. Preferred exemplary substrate temperatures of this invention range from −30° to 0° C., 0° to 20° C., 100 to 30° C., 20° to 40° C., 30° to 60° C., 40° to 80° C., 50° to 100° C.

In certain embodiments, the deposition chamber is at a pressure below atmospheric pressure or 750 torr (105 Pascals (Pa)) or less, or 100 torr (13332 Pa) or less. In other embodiments, the pressure of the deposition chamber is maintained at a range of about 0.1 torr (13 Pa) to about 10 torr (1333 Pa). In a preferred embodiment, the pressure of the deposition chamber is maintained at a range of about 2 torr (266 Pa) to about 5 torr (667 Pa).

In this method two, or more, molecules of an alkoxy-functionalized cyclosiloxane compound represented by Formulas A, B, or C, below, may be introduced into the deposition chamber:

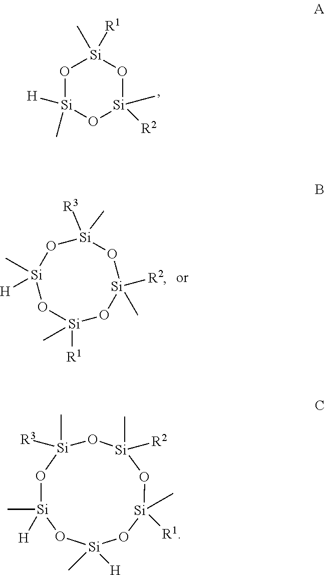

In each of the compounds represented above, R¹ is and alkoxy-group having 1 to 10 carbon atoms. R² may be H, or an alkoxy-group having 1 to 10 carbon atoms. Finally, R³, if present, may be H, or an alkoxy-group having 1 to 10 carbon atoms.

In a preferred embodiment of the method, the R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this embodiment, R² is H, and R³ is also H.

In an additional preferred embodiment of this method, R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this particular embodiment, R² is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, cyclopentoxy, cyclohexoxy, and combinations thereof. In this preferred embodiment, R³ is H.

In another preferred embodiment of this method, R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this preferred embodiment R² is H, and R³ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof.

In a last preferred embodiment of this method, R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this last preferred embodiment, R² is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. Finally, in this embodiment, R³ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof.

Moving on, in a more preferred embodiment of this method, the alkoxy-functionalized cyclosiloxane compound is generally depicted by Formula A, and this alkoxy-functionalized cyclosiloxane compound is selected from the group consisting of:

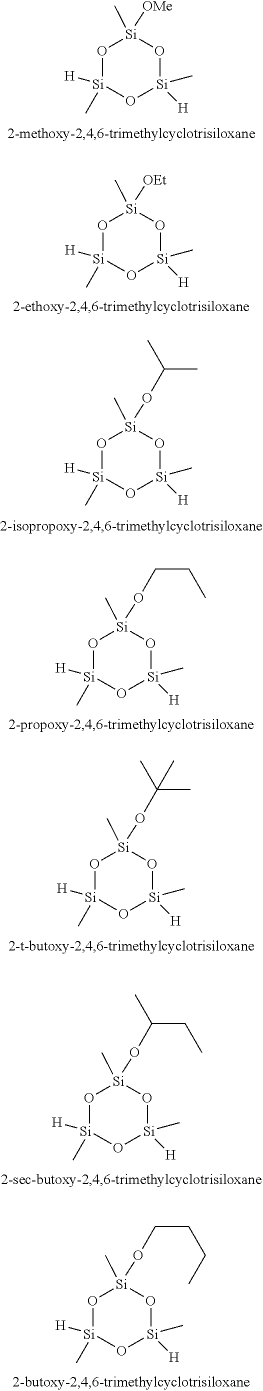

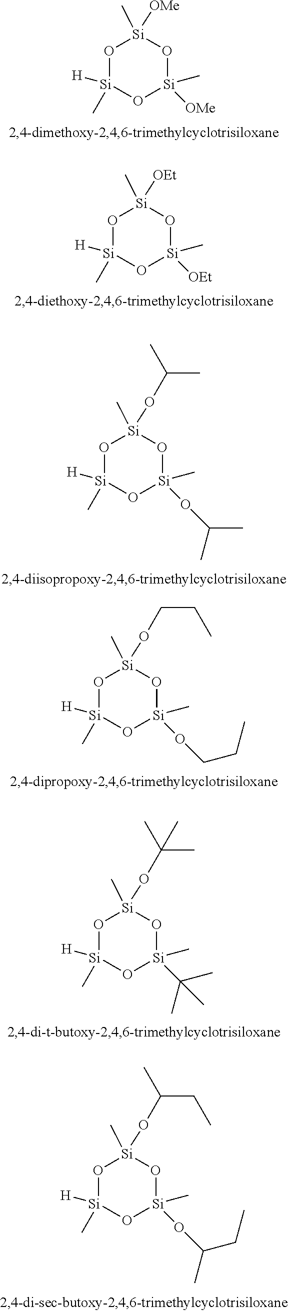 [SMILES: CO[Si]1(C)O[SiH](C)O[Si](C)(OC)O1 ; CCO[Si]1(C)O[SiH](C)O[Si](C)(OCC)O1 ; CC(C)O[Si]1(C)O[SiH](C)O[Si](C)(OC(C)C)O1 ; CCCO[Si]1(C)O[SiH](C)O[Si](C)(OCCC)O1 ; C[SiH]1O[Si](C)(OC(C)(C)C)O[Si](C)(C(C)(C)C)O1 ; CCC(C)O[Si]1(C)O[SiH](C)O[Si](C)(OC(C)CC)O1]

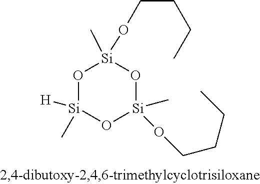 [SMILES: CCCCO[Si]1(C)O[SiH](C)O[Si](C)(OCCCC)O1]

In another more preferred embodiment of this method, the alkoxy-functionalized cyclosiloxane compound is generally depicted by Formula B, and this alkoxy-functionalized cyclosiloxane compound is selected from the group consisting of:

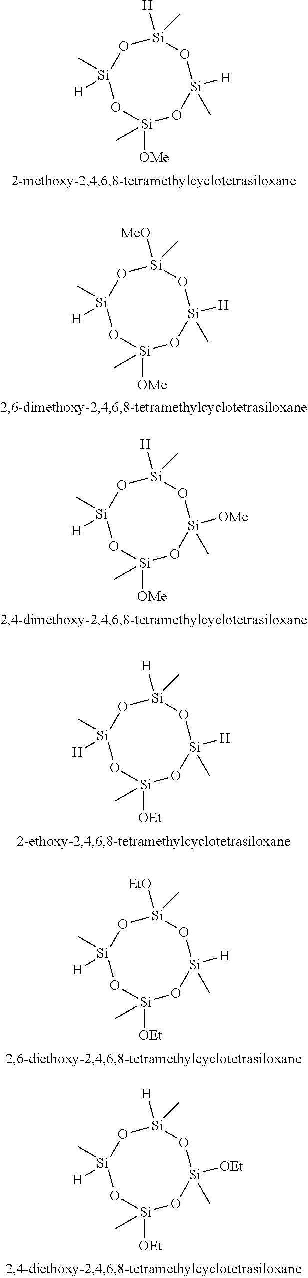 [SMILES: CO[Si]1(C)O[SiH](C)O[SiH](C)O[SiH](C)O1 ; CO[Si]1(C)O[SiH](C)O[Si](C)(OC)O[SiH](C)O1 ; CO[Si]1(C)O[SiH](C)O[SiH](C)O[Si](C)(OC)O1 ; CCO[Si]1(C)O[SiH](C)O[SiH](C)O[SiH](C)O1 ; CCO[Si]1(C)O[SiH](C)O[Si](C)(OCC)O[SiH](C)O1 ; CCO[Si]1(C)O[SiH](C)O[SiH](C)O[Si](C)(OCC)O1]

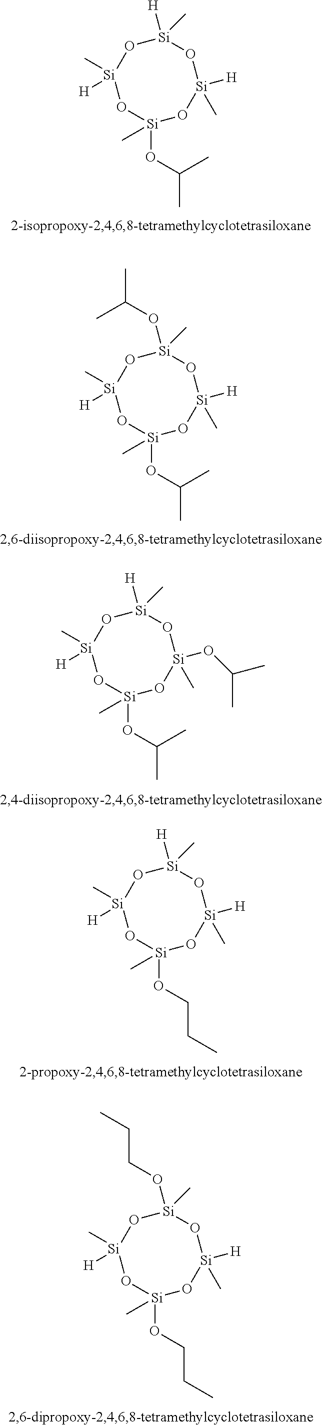

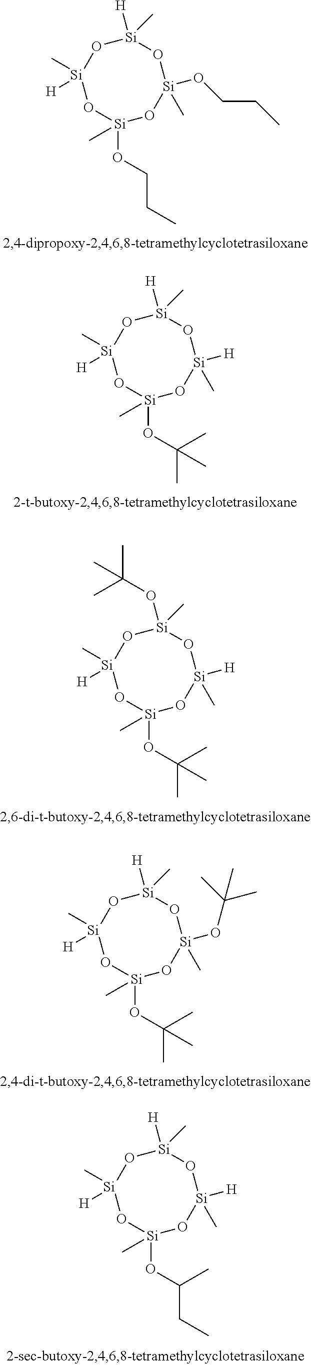

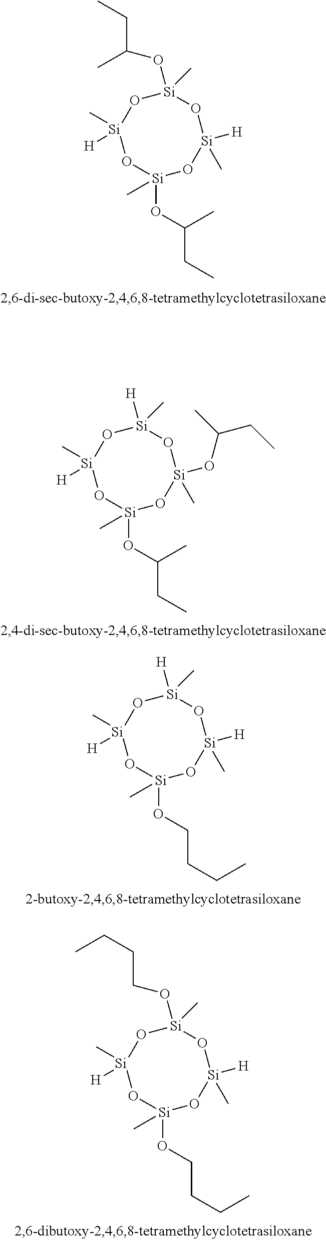

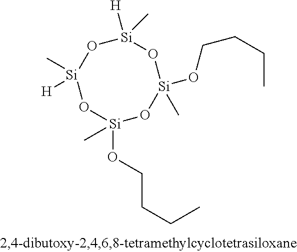 [SMILES: CCCCO[Si]1(C)O[SiH](C)O[SiH](C)O[Si](C)(OCCCC)O1]

Finally, in another more preferred embodiment of this method, the alkoxy-functionalized cyclosiloxane compound is generally depicted by Formula C, and this alkoxy-functionalized cyclosiloxane compound is selected from the group consisting of:

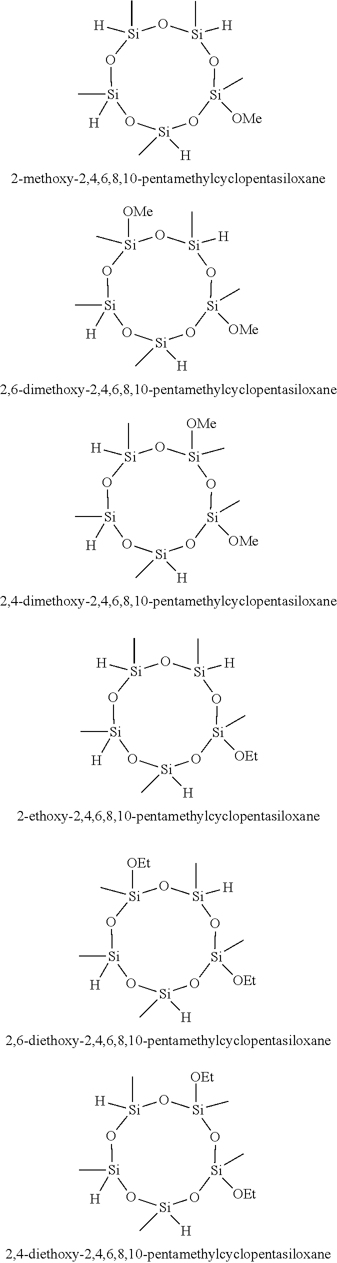

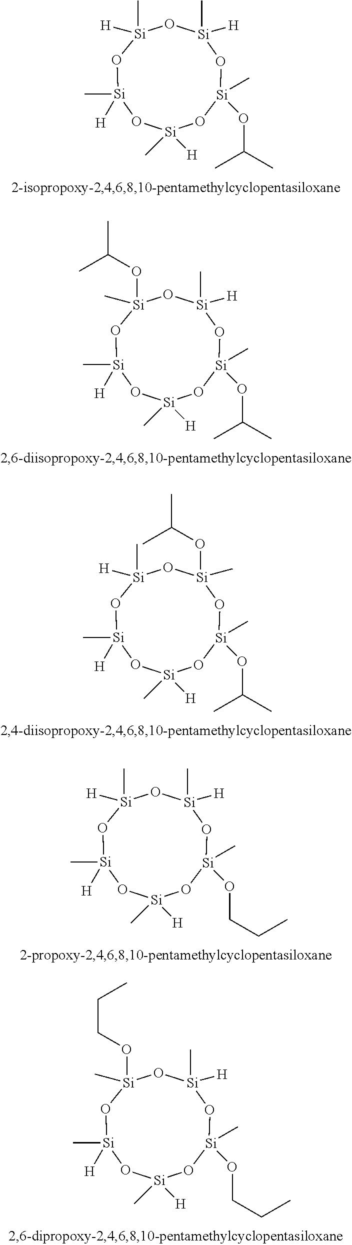

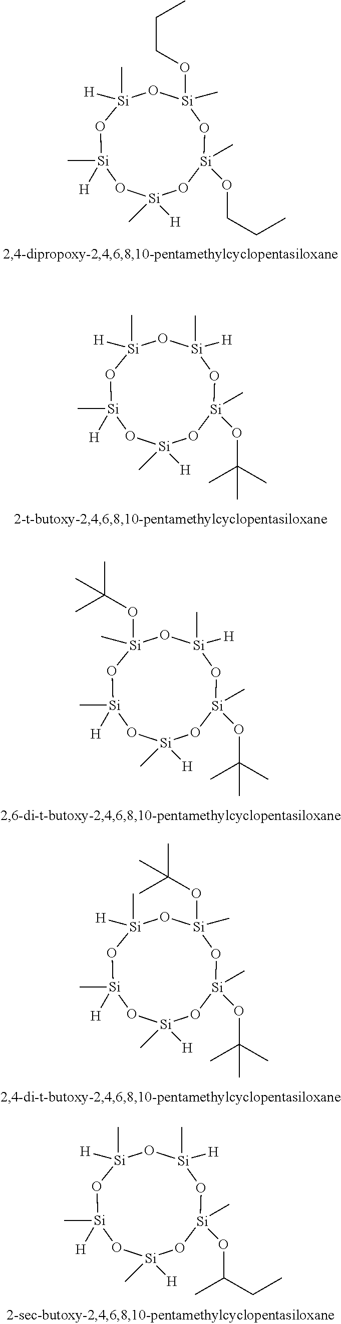

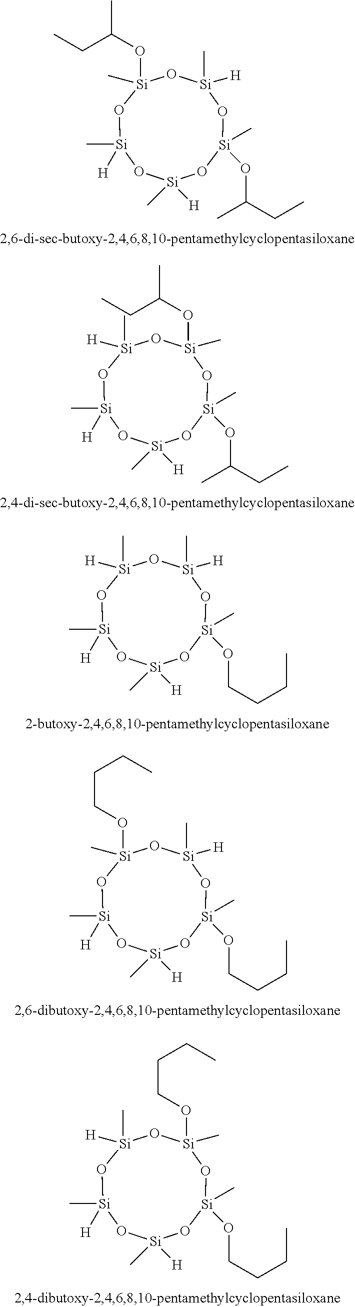

The Applicant also envisions that in some instances of this method a mixture of two, or more, alkoxy-functionalized cyclosiloxane molecules depicted by Formulas A, B or C, may be preferable to only one of the alkoxy-functionalized cyclosiloxane compounds depicted by Formulas A, B, or C. A mixture of these two, or more, alkoxy-functionalized cyclosiloxane molecules may, for example, comprise a mixture of molecules of Formula A and Formula B. In another instance, the mixture may comprise molecules of Formula A and Formula C. In an additional instance, the mixture may comprise two, or molecules, of Formula B and Formula C. Finally, the two, or more, molecules, may comprise compounds of Formula A, Formula B, and Formula C.

The two, or more, molecules of the alkoxy-functionalized cyclosiloxane compound represented by Formulas A, B, or C, may be exposed to a plasma in the deposition chamber. This exposure to the plasma may induce a reaction between the two, or more, molecules, and thus create a flowable liquid, or oligomer. made from the two, or more, molecules of the alkoxy-functionalized cyclosiloxane compound represented by Formulas A, B, or C. Then, this flowable liquid, or oligomer, may at least partially fill the surface feature of the substrate and thus create the silicon-containing film.

In this aspect of the invention, the plasma of this method may be a pulsed plasma, a helicon plasma, a high density plasma, an inductively coupled plasma, or a remote plasma, and combinations thereof. In certain embodiments, a secondary RF frequency source can be used to modify the plasma characteristics at the substrate surface The plasma may comprise a direct plasma-generated process in which plasma is directly generated in the deposition chamber (i.e., an in-situ plasma). Alternatively, the method may comprise a plasma which is generated outside of the deposition chamber and supplied into the deposition chamber (i.e., a remote plasma). This plasma may also comprise an in-situ plasma, and a remote plasma, occurring simultaneously, or sequentially, during the method to deposit a silicon-containing film described herein.

In one embodiment of this method, the introducing step further comprises introducing an inert gas into the deposition chamber. In this instance, the inert gas is selected from the group consisting of helium, argon, xenon, and mixtures thereof, and the plasma in the exposing step is an in-situ plasma. In this alternative, atoms of the inert gas are not incorporated into the into the flowable liquid, or oligomer, made from the two, or more, molecules of the alkoxy-functionalized cyclosiloxane compound represented by the Formulas A, B or C, by exposure to the in-situ plasma in the deposition chamber, thereby creating a silicon-containing film comprising silicon and carbon.

In an additional embodiment of this method, the introducing step further comprises introducing a nitrogen source into the deposition chamber, wherein the nitrogen source is selected from the group consisting of N₂, ammonia, NF₃, an organoamine, and mixtures thereof. The plasma in the exposing step of this additional embodiment of the method is an in-situ plasma, and the nitrogen atoms of the nitrogen source are incorporated into the flowable liquid, or oligomer, made from the two, or more, molecules of the alkoxy-functionalized cyclosiloxane compound represented by the Formulas A, B or C, by exposure to the in-situ plasma in the deposition chamber. This method thereby may create a silicon-containing film comprising silicon, carbon, and nitrogen.

In another alternative of this method, the introducing step further comprises introducing an oxygen source selected from the group consisting of water, oxygen, ozone, nitric oxide, nitrous oxide, carbon monoxide, carbon dioxide, and combinations thereof. The plasma in the exposing step is an in-situ plasma, and the oxygen atoms of the oxygen source are incorporated into the flowable liquid, or oligomer, made from the two, or more, molecules of the alkoxy-functionalized cyclosiloxane compound represented by the Formulas A, B or C, by exposure to the in-situ plasma in the deposition chamber. The silicon-containing film created in this instance may comprise silicon, carbon, and oxygen.

In another alternative of the method disclosed herein, the plasma in the exposing step is a remote plasma comprising an inert gas. The inert gas may be selected from the group consisting of helium, argon, xenon, and mixtures thereof, and the atoms of the inert gas are not incorporated into the into the flowable liquid, or oligomer, made from the two, or more, molecules of the alkoxy-functionalized cyclosiloxane compound represented by the Formulas A, B or C, after exposure to the remote plasma in the deposition chamber. In this instance, the silicon-containing film may comprise silicon and carbon.

In another embodiment of the method disclosed herein, the plasma in the exposing step is a remote plasma comprising a nitrogen source, and the nitrogen source may be selected from the group consisting of N2, ammonia, NF3, an organoamine, and mixtures thereof. In this instance, the nitrogen atoms of the nitrogen source are incorporated into the flowable liquid, or oligomer, made from the two, or more, molecules of the alkoxy-functionalized cyclosiloxane compound represented by the Formulas A, B or C, after exposure to the remote plasma in the deposition chamber. The silicon-containing film created in this instance may comprise silicon, carbon, and nitrogen.

In another alternate embodiment of the method disclosed herein, the plasma in the exposing step is a remote plasma comprising an oxygen source. The oxygen source may be selected from the group consisting of water, oxygen, ozone, nitric oxide, nitrous oxide, carbon monoxide, carbon dioxide, and combinations thereof. In this particular alternate embodiment, the oxygen atoms of the oxygen source are incorporated into the flowable liquid, or oligomer, made from the two, or more, molecules of the alkoxy-functionalized cyclosiloxane compound represented by the Formulas A, B or C, after exposure to the remote plasma in the deposition chamber. As such, the silicon-containing film may comprise silicon, carbon, and oxygen.

The method may additionally include pre-treating the substrate in a pre-treatment step before placing it into the deposition chamber. The pre-treatment step may be selected from the group consisting of a plasma treatment, a thermal treatment, a chemical treatment, exposure to ultraviolet light, exposure to an electron beam, and combinations thereof. These pre-deposition treatments may occur under an atmosphere selected from inert, oxidizing, and/or reducing.

The method of depositing a silicon-containing film may further comprise a post-treatment in a post-treatment step. In this step, the post-treatment may be selected from the group consisting of an ultraviolet cure of the silicon-containing film, a plasma annealing of the silicon-containing film, an infrared treatment of the silicon-containing film, and combinations thereof, thereby densifying the silicon-containing film. The post-treatment step may further comprise a post-treatment non-oxygenated thermal anneal, or an oxygenated thermal anneal, thereby densifying the silicon-containing film, as an alternative, or in combination with the group of post-treatment methods listed just above.

The alkoxy-functionalized compounds disclosed herein can be used to provide a rapid and uniform deposition of a flowable silicon-containing film. The compounds described herein may be used with another reactant containing water and optional co-solvents, surfactants and other additives and deposited onto a substrate. Distribution or delivery of the compounds to the deposition chamber may be achieved by direct liquid injection, spraying, and the like.

The use of inert gas, vacuum, heat or external energy source (light, heat, plasma, e-beam, etc.) to remove unreacted volatile species, including solvents and unreacted water may follow to facilitate the condensation of the film. The compounds of the present invention may preferably be delivered to a substrate contained in a deposition chamber as a gas phase, liquid droplets, mist, fog, aerosol, sublimed solid, or combination thereof with water and optionally co-solvents and other additives also added as a process fluid such as a gas, vapor, aerosol, mist, or combination thereof. Preferably, the oligomerized, or polymerized, compounds of the present invention condense into a condensed film on the surface of the substrate, which may advantageously be held at a temperature below that of the walls of the chamber. Unreacted precursor compounds, water and optional co-solvents and additives may be removed by gas purge, vacuum, heating, addition of external radiation (light, plasma, electron beam, etc.), until a stable solid silicon-containing film is obtained.

In any of the above, or in an alternative embodiment, the flowable liquid or oligomer may be post-treated at one or more temperatures ranging from about 100° C. to about 1000° C. to density at least a portion of the materials. This thermal anneal treatment can be performed in an inert environment, vacuum (<760 Torr), or under oxygen environment.

As such, based on the above, in a third aspect of this invention, a film on a substrate is disclosed. The film may comprise a flowable liquid, or oligomer, comprising two, or more, oligomerized, or polymerized, molecules of an alkoxy-functionalized cyclosiloxane compound depicted by Formulas A, B, or C,

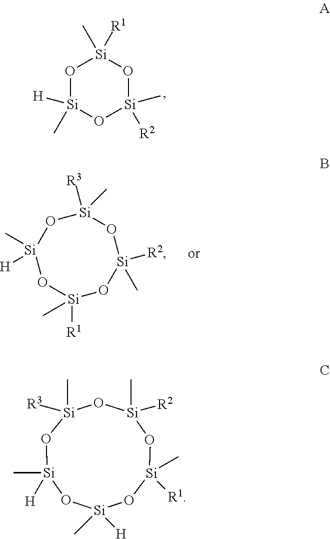

In each of the compounds represented above, R¹ is and alkoxy-group having 1 to 10 carbon atoms. R² may be H, or an alkoxy-group having 1 to 10 carbon atoms. Finally, R³, if present, may be H, or an alkoxy-group having 1 to 10 carbon atoms.

In one embodiment of this film, R¹ of the two, or more, oligomerized, or polymerized, molecules of the alkoxy-functionalized cyclosiloxane compound may be an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this embodiment, R² is H, and R³ is also H.

In another embodiment of this film, R¹ of the two, or more, oligomerized, or polymerized, molecules of the alkoxy-functionalized cyclosiloxane compound may be an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this particular embodiment, R² may be an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, cyclopentoxy, cyclohexoxy, and combinations thereof. In this embodiment, R³ is H.

In another embodiment of this film, R¹ of the two, or more, oligomerized, or polymerized, molecules of the alkoxy-functionalized cyclosiloxane compound may be an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this preferred embodiment R² is H, and R³ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof.

In another embodiment of this film, R¹ of the two, or more, oligomerized, or polymerized, molecules of the alkoxy-functionalized cyclosiloxane compound may be an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. In this last preferred embodiment, R² is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof. Finally, in this embodiment, R³ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof.

Moving on, in a more preferred embodiment of this film, the two, or more, oligomerized, or polymerized, molecules of the alkoxy-functionalized cyclosiloxane compound are generally depicted by Formula A, and selected from the group consisting of:

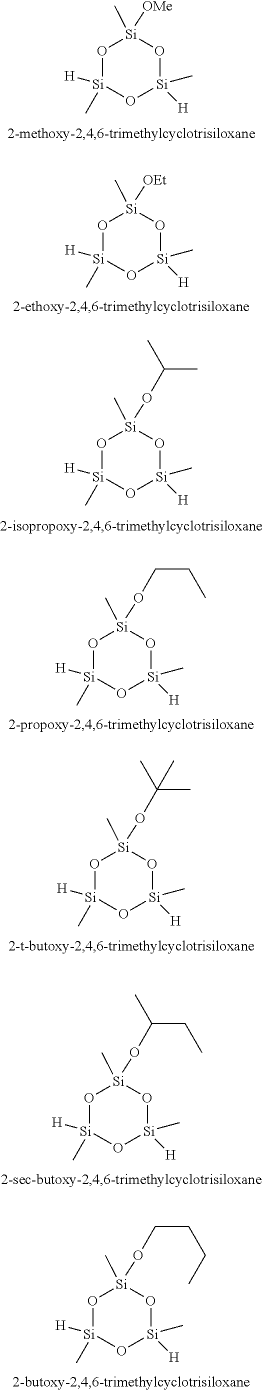

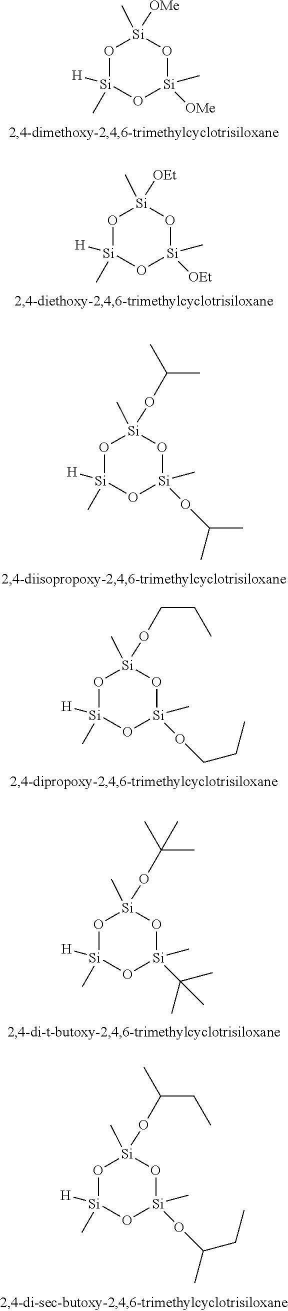 [SMILES: CO[Si]1(C)O[SiH](C)O[Si](C)(OC)O1 ; CCO[Si]1(C)O[SiH](C)O[Si](C)(OCC)O1 ; CC(C)O[Si]1(C)O[SiH](C)O[Si](C)(OC(C)C)O1 ; CCCO[Si]1(C)O[SiH](C)O[Si](C)(OCCC)O1 ; C[SiH]1O[Si](C)(OC(C)(C)C)O[Si](C)(C(C)(C)C)O1 ; CCC(C)O[Si]1(C)O[SiH](C)O[Si](C)(OC(C)CC)O1]

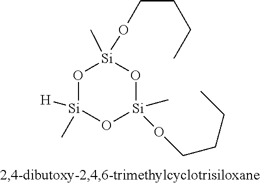 [SMILES: CCCCO[Si]1(C)O[SiH](C)O[Si](C)(OCCCC)O1]

In another more preferred embodiment of this film, the two, or more, oligomerized, or polymerized, molecules of the alkoxy-functionalized cyclosiloxane compound are generally depicted by Formula B, and selected from the group consisting of:

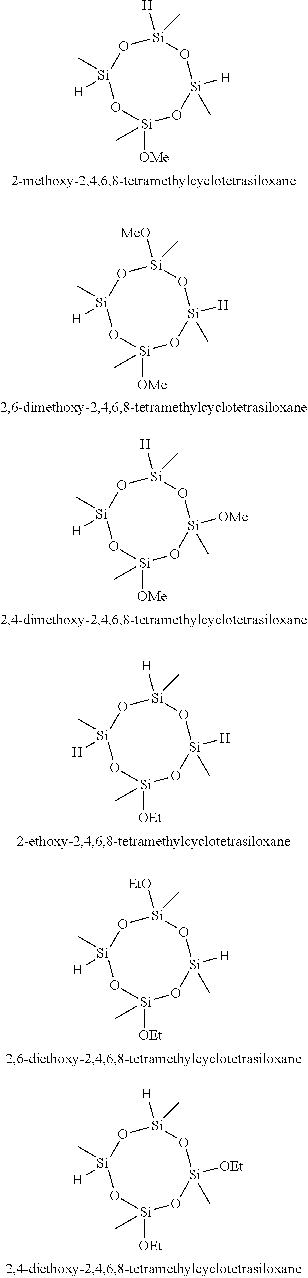 [SMILES: CO[Si]1(C)O[SiH](C)O[SiH](C)O[SiH](C)O1 ; CO[Si]1(C)O[SiH](C)O[Si](C)(OC)O[SiH](C)O1 ; CO[Si]1(C)O[SiH](C)O[SiH](C)O[Si](C)(OC)O1 ; CCO[Si]1(C)O[SiH](C)O[SiH](C)O[SiH](C)O1 ; CCO[Si]1(C)O[SiH](C)O[Si](C)(OCC)O[SiH](C)O1 ; CCO[Si]1(C)O[SiH](C)O[SiH](C)O[Si](C)(OCC)O1]

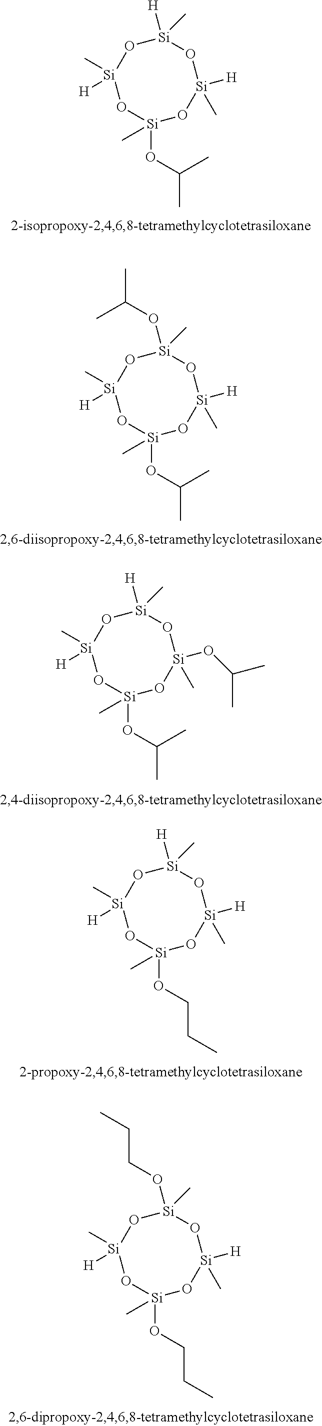

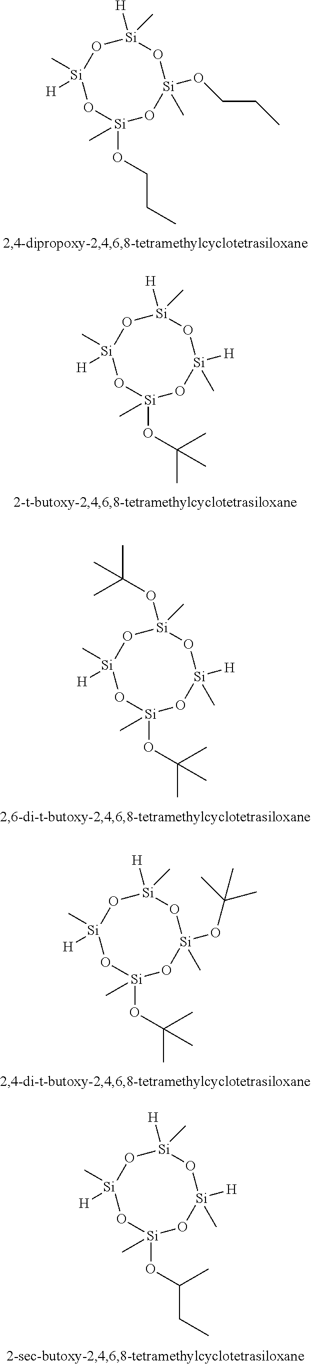

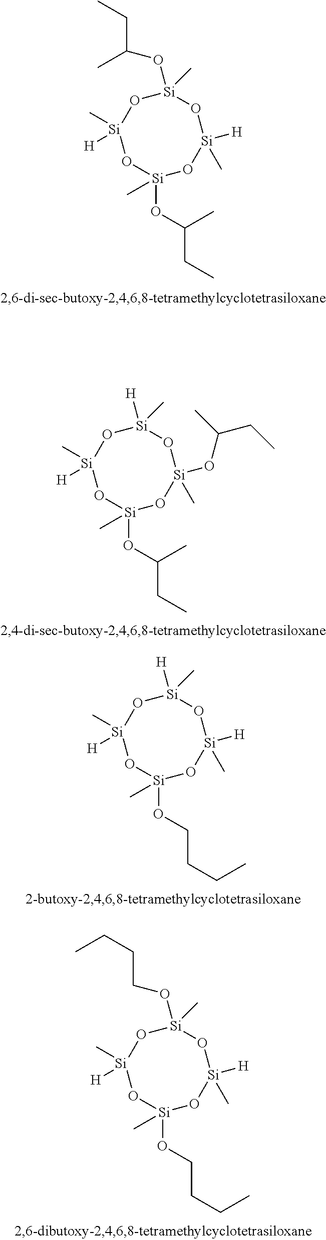

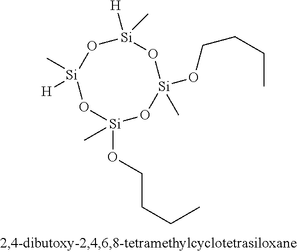 [SMILES: CCCCO[Si]1(C)O[SiH](C)O[SiH](C)O[Si](C)(OCCCC)O1]

In an additional more preferred embodiment of this film, the two, or more, oligomerized, or polymerized, molecules of the alkoxy-functionalized cyclosiloxane compound are generally depicted by Formula C, and selected from the group consisting of:

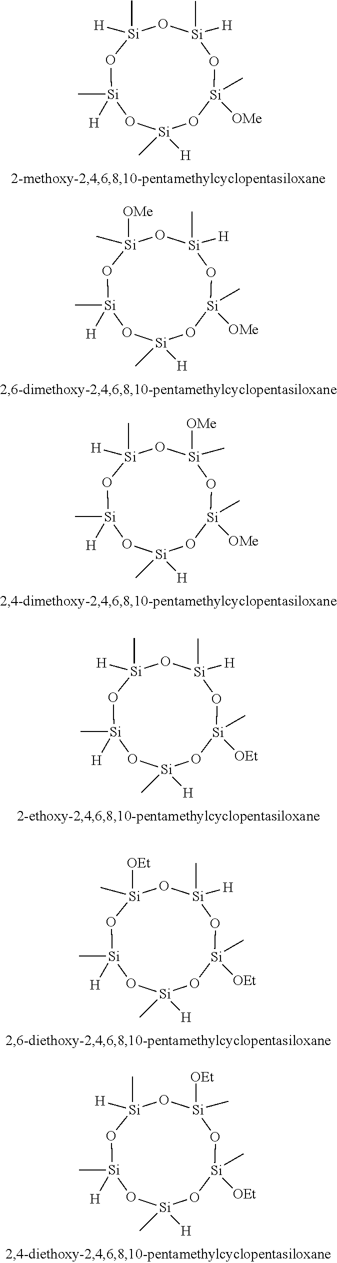

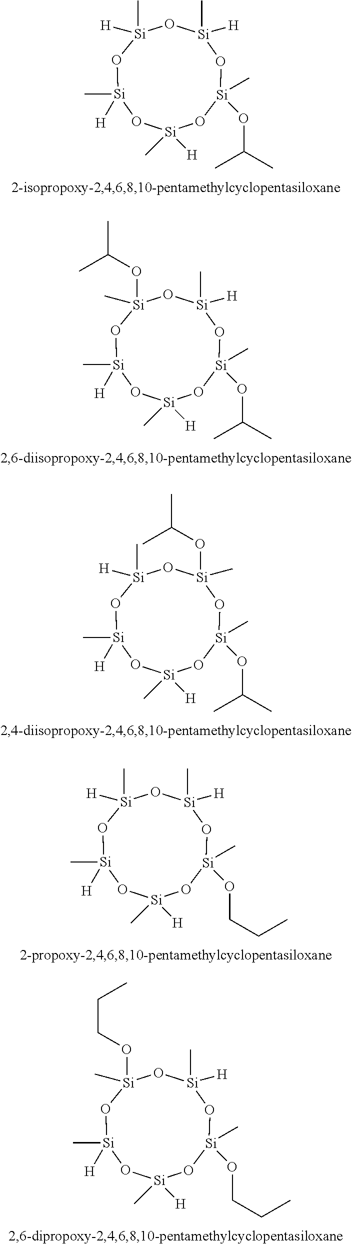

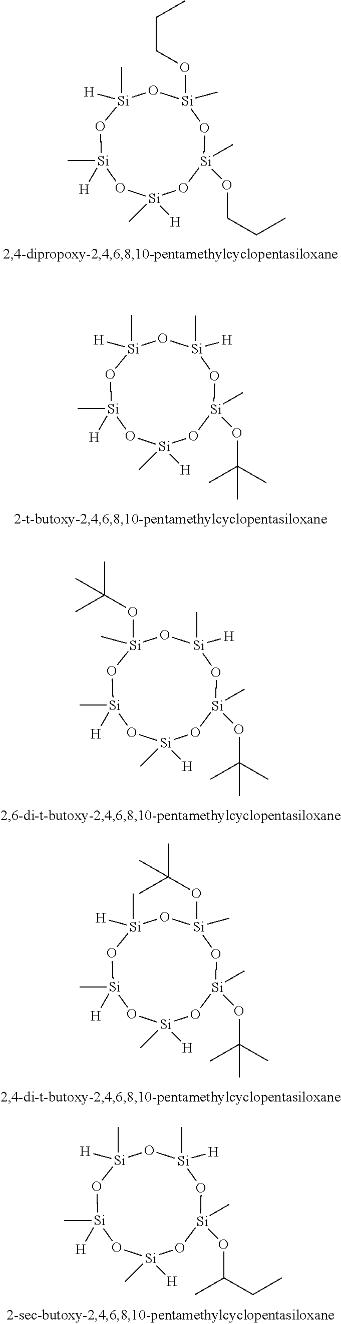

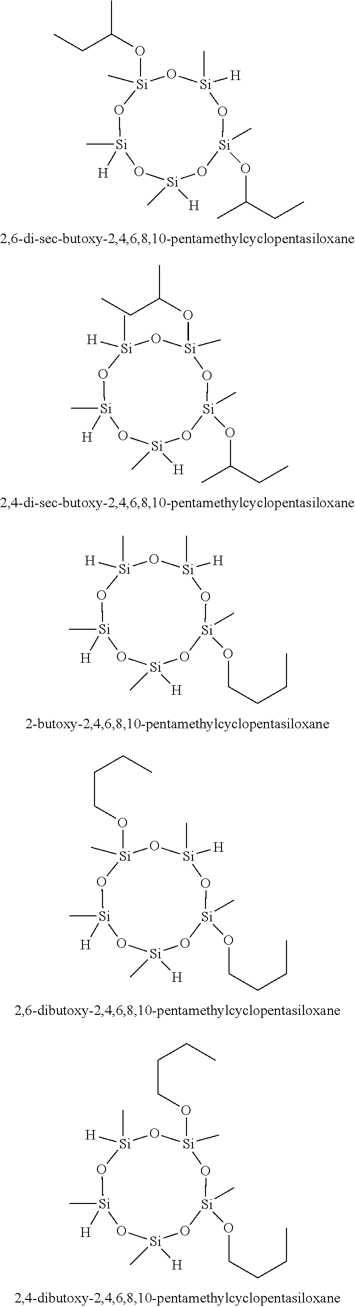

The alkoxy-functionalized cyclosiloxane compounds represented by Formulas A, B, or C, disclosed herein may be stored, transported and delivered in glass, plastic, or metallic containers or other suitable containers known in the art.

Plastic or glass lined metallic vessels or containers may also be used. Preferably, the material is stored and delivered from a hermetically sealed high purity stainless steel or nickel alloy vessel having inert gas in the head space. Most preferably, the material is stored and delivered from a hermetically sealed high purity stainless steel or nickel alloy vessel equipped with a down tube and an outlet in communication with the vapor space of the vessel; allowing the product to be delivered either as a liquid from the downtube or as a vapor from the outlet connection in communication with the vapor phase. In the latter case, the down-tube may be optionally used to introduce a carrier gas into the vessel to promote the vaporization of the mixture. In this embodiment, the downtube and vapor outlet connections are equipped with high integrity packless valves. While delivery of the liquid is preferred to avoid partitioning of the components of this formulation described herein, it should be noted that the formulations of the present invention match the vapor pressure of the components closely enough to enable the formulation to be delivered as a vapor mixture. Stainless steel may preferably be chosen from UNS alloy numbers S31600, S31603, S30400, S30403, S31700, S31703, S31500, S31803, S32750, and S31254. Nickel alloys may preferably be chosen from UNS alloy numbers N06625, N10665, N06022, N10276, and N06007. Most preferably, the vessels are made from alloys S31603 or N06022, either uncoated, internally electro polished or internally coated with a fluoropolymer.

### Deposition of Alkoxy-Functionalized Cyclosiloxane Films

General Experimental Materials and Equipment for Film Deposition

FCVD films were deposited onto medium resistivity (8-12 Ωcm) single crystal silicon wafer substrates and Si pattern wafers. For the pattern wafers, the preferred pattern width is 20-100 nm with the aspect ratio of 5:1-20:1. The depositions were performed on a modified FCVD chamber on an Applied Materials Precision 5000 system, using a dual plenum showerhead. The chamber was equipped with direct liquid injection (DLI) delivery capability. The precursors were liquids with delivery temperatures dependent on the precursor's boiling point. To deposit the initial flowable silicon oxide films, typical liquid precursor flow rates ranged from about 100 to about 5000 mg/min, preferably 1000 to 2000 mg/min; the chamber pressure ranged from about 0.75-12 Torr, preferably 2 to 5 Torr. Particularly, the remote power was provided by MKS microwave generator from 0 to 3000 W with the frequency of 2.455 GHz, operating from 2 to 8 Torr. To densify the as-deposit flowable films, the films were thermally annealed and/or UV cured in vacuum, or in an oxygen environment, using the modified PECVD chamber at 100-1000° C., preferably 300-400° C. Thickness and refractive index (RI) at 632 nm were measured by a SCI reflectometer or Woollam ellipsometer. The typical film thickness ranged from about 10 to about 2000 nm. Bonding properties hydrogen content (Si—H and C—H) of the silicon-based films were measured and analyzed by a Nicolet transmission Fourier transform infrared spectroscopy (FTIR) tool. X-ray photoelectron spectroscopy (XPS) analysis were performed to determine the elemental composition of the films. A mercury probe was adopted for the electrical properties measurement including dielectric constant, leakage current and breakdown field. The flowability and gap fill effects on an Al patterned wafer were observed by a cross-sectional scanning electron microscopy (SEM) using a Hitachi S-4800 system at a resolution of 2.0 nm.

### Working Example 21—Deposition of 2-ethoxy-2,4,6,8-tetramethylcyclotetrasiloxane with Non-oxygenated Thermal Anneal and UV Cure

2-ethoxy-2,4,6,8-tetramethylcyclotetrasiloxane (2-ethoxy-TMCTS) was used for flowable SiOC film deposition with remote plasma source (RPS). The 2-ethoxy-TMCTS liquid flow was 1500 mg/min, ammonia flow was 1000 sccm, chamber pressure was 4.5 Torr. The substrate temperature was 60° C., and the microwave power was 3000 W. The as deposited films were thermally annealed, in inert environment, at 400° C. for five minutes and then UV cured at 400° C. for five minutes. The thickness and refractive index of the as deposited film was 209.6 nm and 1.444; after the inert thermal anneal the thickness and refractive index was 206.1 nm and 1.433 indicating the loss of some volatile oligomers at elevated temperature.

The dielectric constant of the film after inert thermal anneal was 3.308, which we attribute to some moisture absorption from the dangling bonds of the film. After the UV cure the film has a shrinkage about 16 percent from thermal annealed film and it has a refractive index of 1.414, which indicate the films modification by the UV cure along with the film gaining porosity. The dielectric constant of the UV cured film was 2.931. The elemental composition of the film for this process is 22.6% C, 5.0% N, 39.8% 0, 32.7% Si.

### Working Example 22—Deposition of 2-ethoxy-2,4,6,8-tetramethylcyclotetrasiloxane with Oxygenated Thermal Anneal and UV Cure

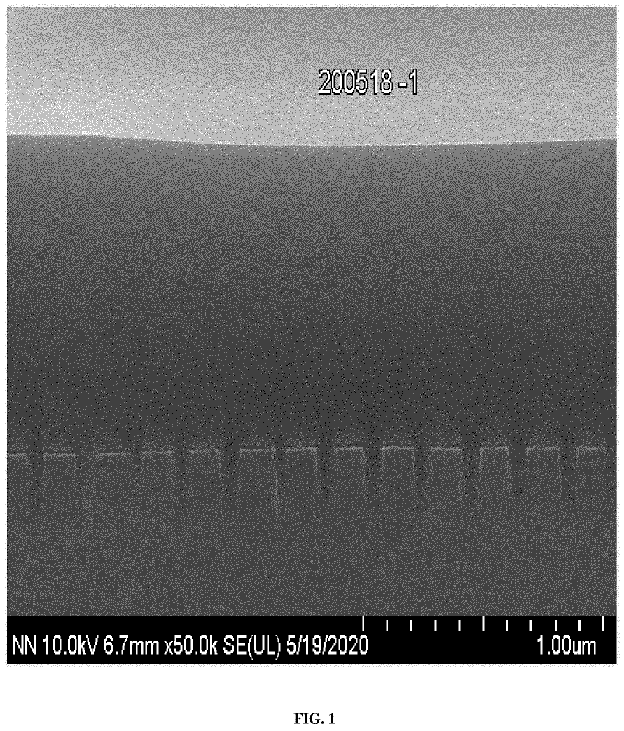

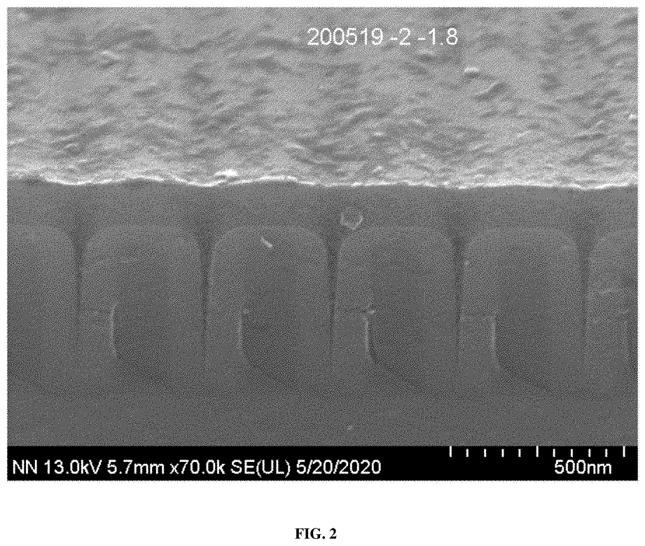

This example is directed to an as deposited film which is thermally annealed in oxygen environment then UV cured. Cross-sectional SEM indicated that good gap-fill was achieved on patterned wafers. FIG. 1 and FIG. 2 showed good gap-fill. The films were thermally annealed, and UV cured. The cross-sectional SEM indicate good gap fill was achieved, as well, for Working Example 22. There are no obvious signs of voiding in the film after UV curing. This is displayed by FIG. 2.

After the UV cure for this process, the percent shrinkage in thickness was around 12 percent and the refractive index was 1.394. The dielectric constant for this film was 2.791. The elemental composition of the following both the oxygen thermal anneal and then a UV cure is 16.4% C, 1.4% N, 48.9% O, 33.3% Si.

### Working Example 23—Deposition of 2-isopropoxy-2,4,6,8-tetramethylcyclotetrasiloxane with Non-oxygenated Thermal Anneal and UV Cure

FCVD films were deposited with 2-Isopropoxy-2,4,6,8-tetramethylcyclotetrasiloxane (2-Isopropoxy-TMCTS) and following the deposition process reported in Example 1. The 2-isopropoxy-TMCTS liquid flow was 1500 mg/min, ammonia flow was 1000 sccm, chamber pressure was 4.5 Torr. The substrate temperature was 60° C., and the microwave power was 3000 W. The as deposited films were thermally annealed, in inert environment, at 400° C. for five minutes and then UV cured at 400° C. for five minutes.

The thickness and refractive index of the as deposited film was 281.4 nm and 1.386; after the inert thermal anneal and UV cure the thickness and refractive index was 188.7 nm and 1.406. The increase in the film's refractive index post UV cure indicates densification. After the UV cure the film has a shrinkage about 32 percent. The dielectric constant of the post UV cured film was 3.075, and the elemental composition of the film was 23.4% C, 4.9% N, 37.9% O, 33.8% Si.

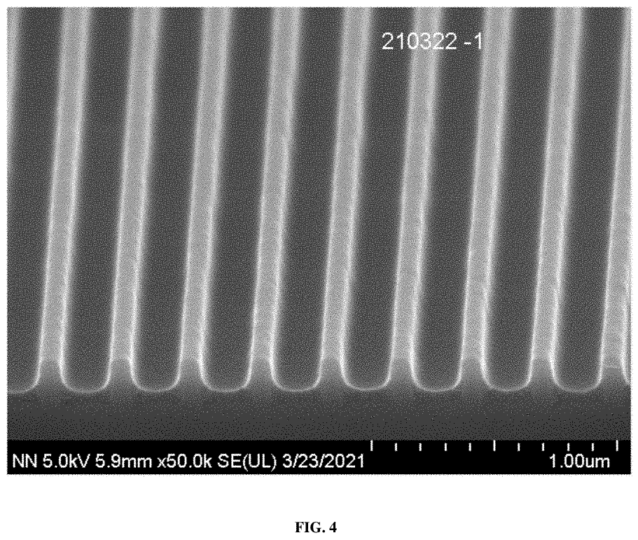

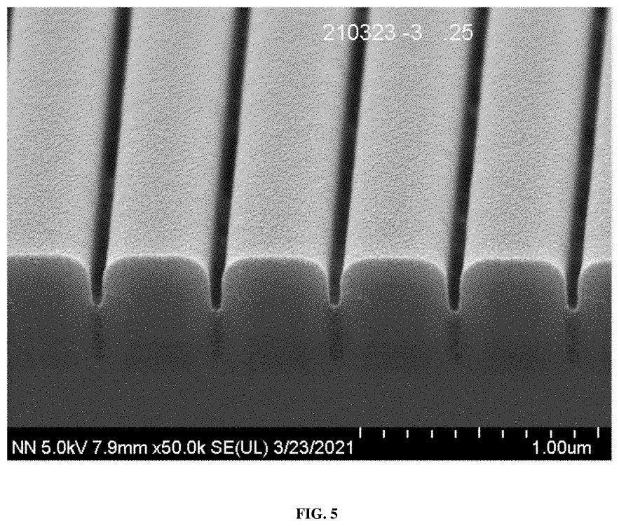

Cross-sectional SEM indicated that good gap-fill was achieved on patterned wafers. The as deposited 2-isopropoxy-TMCTS film depicted in FIG. 4, and the post thermal and UV cured film in FIG. 5. FIG. 5 suggests that no obvious signs of voiding occurred from the UV curing process.

### Working Example 24—Deposition of 2-isopropoxy-2,4,6,8-tetramethylcyclotetrasiloxane with Non-oxygenated Thermal Anneal and UV Cure

Another embodiment involves the as deposited films thermally annealed in oxygen environment at 400° C. for five minutes then UV cured at 400° C. for five minutes. After the UV cure for this process, the percent shrinkage in thickness was around 31 percent and the refractive index was 1.371. The dielectric constant for this film was 2.921. The elemental composition of the following both the oxygen thermal anneal and then a UV cure is 19.8% C, 1.9% N, 44.5% O, 33.8% Si.

### Working Example 25—Electrical Breakdown Measurements of Films made 2-ethoxy-2,4,6,8-tetramethylcyclotetrasiloxane, and 2-isopropoxy-2,4,6,8-tetramethylcyclotetrasiloxane

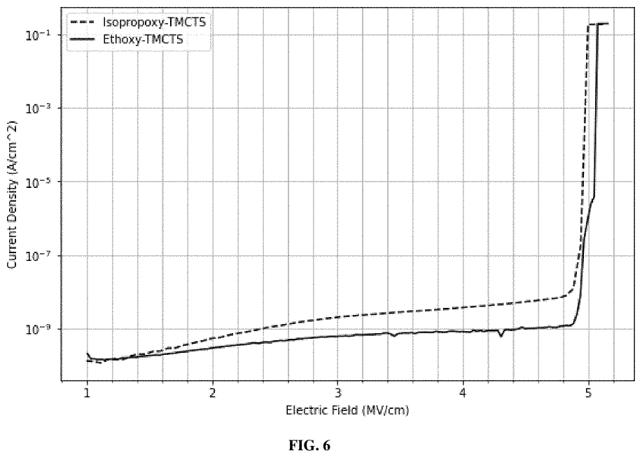

Flowable films were deposited with 2-isopropoxy-TMCTS and 2-ethoxy-TMCTS and after these films were thermally annealed and UV cured, electrical breakdown measurements were performed. The electrical breakdown results are depicted in FIG. 6.

The 2-isopropoxy-TMCTS film was thermally annealed in oxygen environment at 400° C. and UV cured at 300° C., and the 2-ethoxy-TMCTS film was thermally annealed in oxygen environment at 400° C. and UV cured at 300° C.

Both the 2-isopropoxy-TMCTS and 2-ethoxy-TMCTS films in FIG. 6 have similar breakdown points around 4.9 MV/cm, but 2-isopropoxy-TMCTS has slightly higher current density, which suggests that 2-Isopropoxy-TMCTS has slightly higher current leakage in comparison to 2-ethoxy-TMCTS.

The above description is meant to be representative only, and thus modifications may be made to the embodiments described herein without departing from the scope of the disclosure. Thus, these modifications fall within the scope of the present disclosure, and are intended to fall within the appended claims.

What is claimed is:

1. A composition, comprising:
an alkoxy-functionalized cyclosiloxane compound depicted by Formulas A, B, or C, 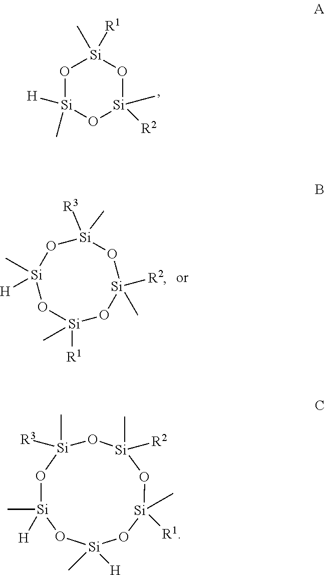
wherein R¹ is an alkoxy-group having 1 to 10 carbon atoms;
wherein R² is H, or is an alkoxy-group having 1 to 10 carbon atoms; and
wherein R³ is H, or is an alkoxy-group having 1 to 10 carbon atoms.

2. The composition according to claim 1, wherein R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof, wherein R² is H, and wherein R³ is H.

3. The composition according to claim 1, wherein R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof, wherein R² is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof, and wherein R³ is H.

4. The composition according to claim 1, wherein R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof, wherein R² is H, and wherein R³ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof.

5. The composition according to claim 1, wherein R¹ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof, wherein R² is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof, and wherein R³ is an alkoxy-group selected from the group consisting of a methoxy, an ethoxy, a 1-propoxy, an isopropoxy, a 1-butoxy, a tert-butoxy, a sec-butoxy, a 1-pentoxy, a 2-pentoxy, a 3-pentoxy, a 2-methyl-1-butoxy, a 3-methyl-1-butoxy, a 2-methyl-2-butoxy, a 2-methyl-3-butoxy, a 2,2-dimethyl-1-propoxy, a 1-hexoxy, a 2-hexoxy, a 3-hexoxy, a 2-methyl-1-pentoxy, a 3-methyl-1-pentoxy, a 4-methyl-1-pentoxy, a 2-methyl-2-pentoxy, a 3-methyl-2-pentoxy, a 4-methyl-2-pentoxy, a 2-methyl-3-pentoxy, a 3-methyl-3-pentoxy, a 2,2-dimethyl-1-butoxy, a 2,3-dimethyl-1-butoxy, a 2,3-dimethyl-2-butoxy, a 3,3,-dimethyl-2-butoxy, a 2-ethyl-1-butoxy, a cyclopentoxy, a cyclohexoxy, and combinations thereof.

6. The composition according to claim 1, wherein the alkoxy-functionalized cyclosiloxane compound is selected from the group consisting of:

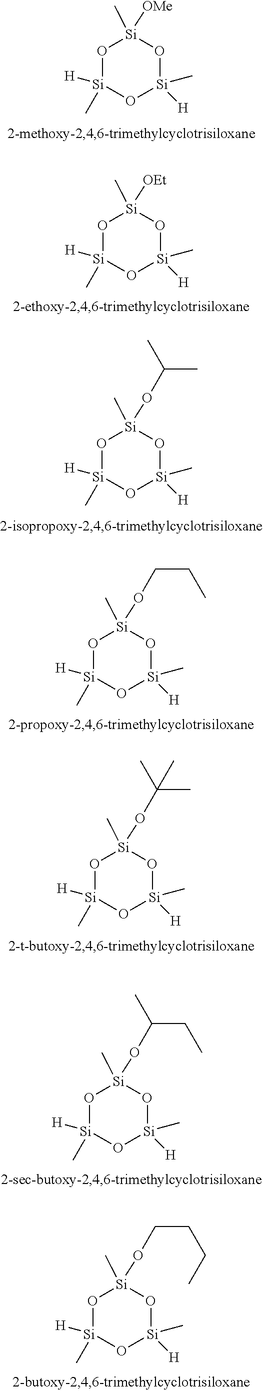

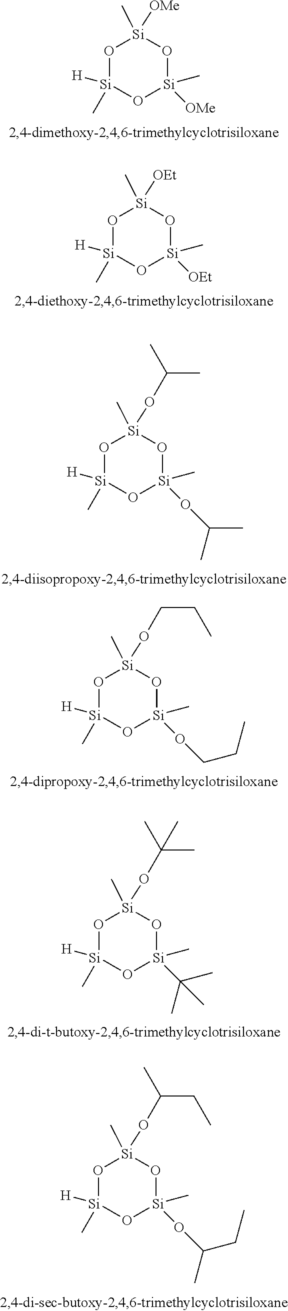 [SMILES: CO[Si]1(C)O[SiH](C)O[Si](C)(OC)O1 ; CCO[Si]1(C)O[SiH](C)O[Si](C)(OCC)O1 ; CC(C)O[Si]1(C)O[SiH](C)O[Si](C)(OC(C)C)O1 ; CCCO[Si]1(C)O[SiH](C)O[Si](C)(OCCC)O1 ; C[SiH]1O[Si](C)(OC(C)(C)C)O[Si](C)(C(C)(C)C)O1 ; CCC(C)O[Si]1(C)O[SiH](C)O[Si](C)(OC(C)CC)O1]

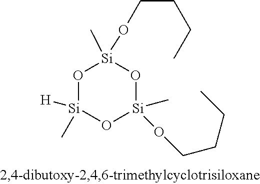 [SMILES: CCCCO[Si]1(C)O[SiH](C)O[Si](C)(OCCCC)O1]

7. The composition according to claim 1, wherein the alkoxy-functionalized cyclosiloxane compound is selected from the group consisting of:

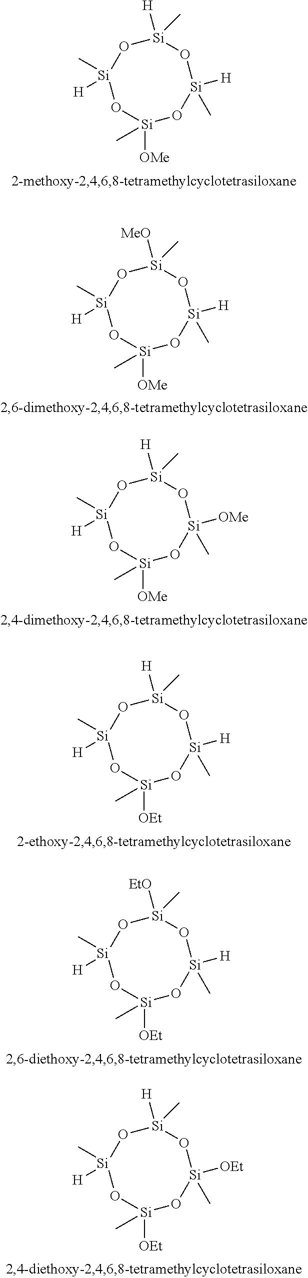 [SMILES: CO[Si]1(C)O[SiH](C)O[SiH](C)O[SiH](C)O1 ; CO[Si]1(C)O[SiH](C)O[Si](C)(OC)O[SiH](C)O1 ; CO[Si]1(C)O[SiH](C)O[SiH](C)O[Si](C)(OC)O1 ; CCO[Si]1(C)O[SiH](C)O[SiH](C)O[SiH](C)O1 ; CCO[Si]1(C)O[SiH](C)O[Si](C)(OCC)O[SiH](C)O1 ; CCO[Si]1(C)O[SiH](C)O[SiH](C)O[Si](C)(OCC)O1]

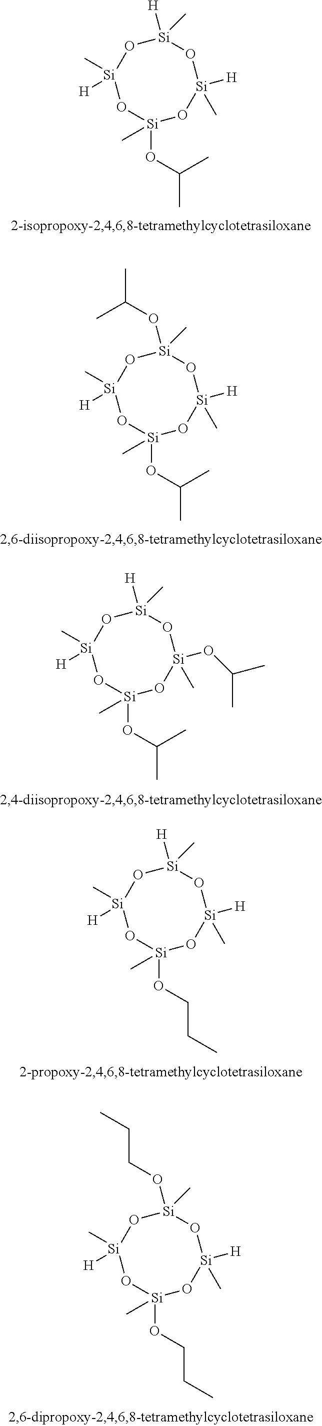

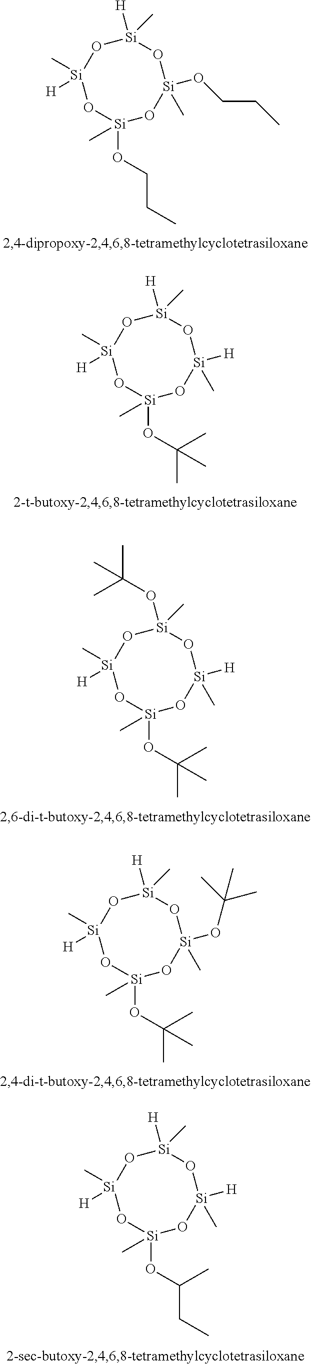

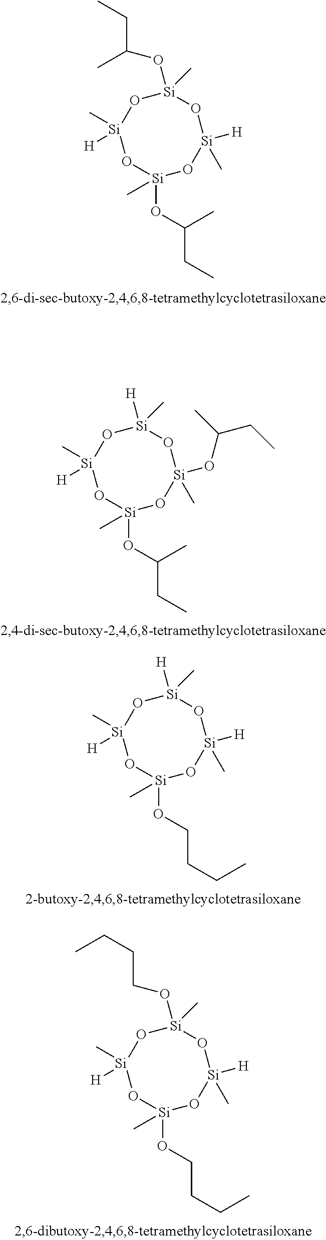

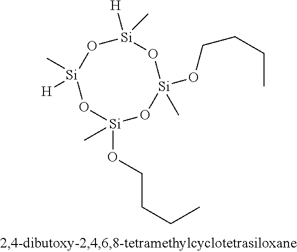 [SMILES: CCCCO[Si]1(C)O[SiH](C)O[SiH](C)O[Si](C)(OCCCC)O1]

8. The composition according to claim 1, wherein the alkoxy-functionalized cyclosiloxane compound is selected from the group consisting of:

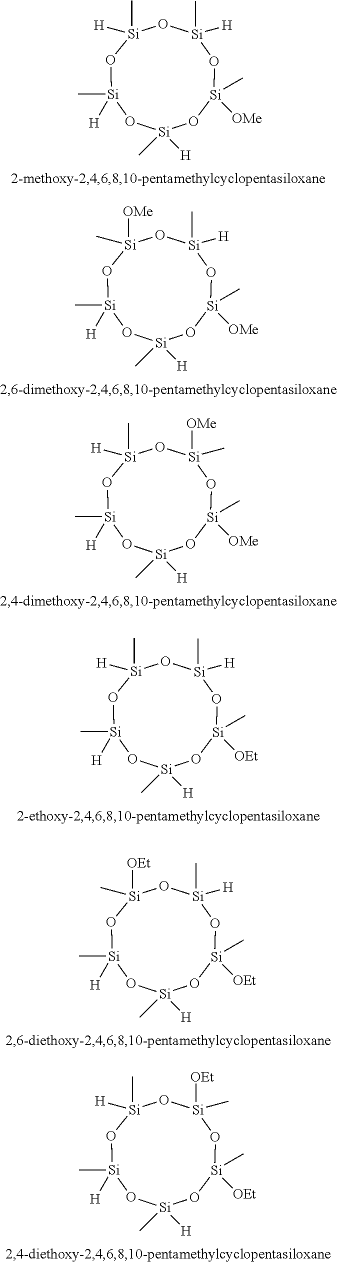

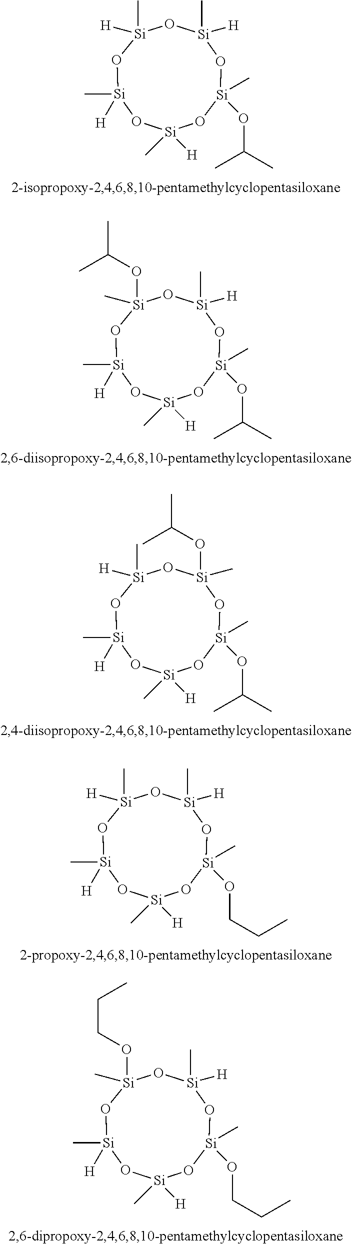

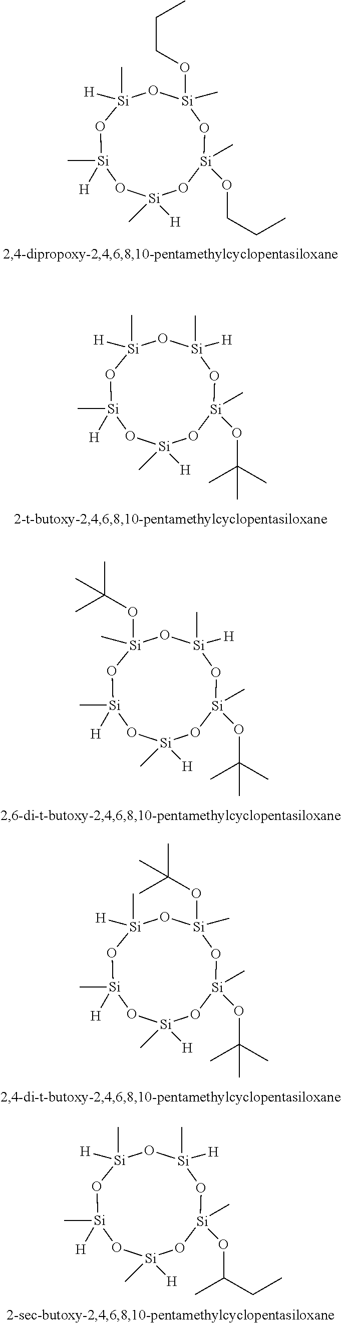

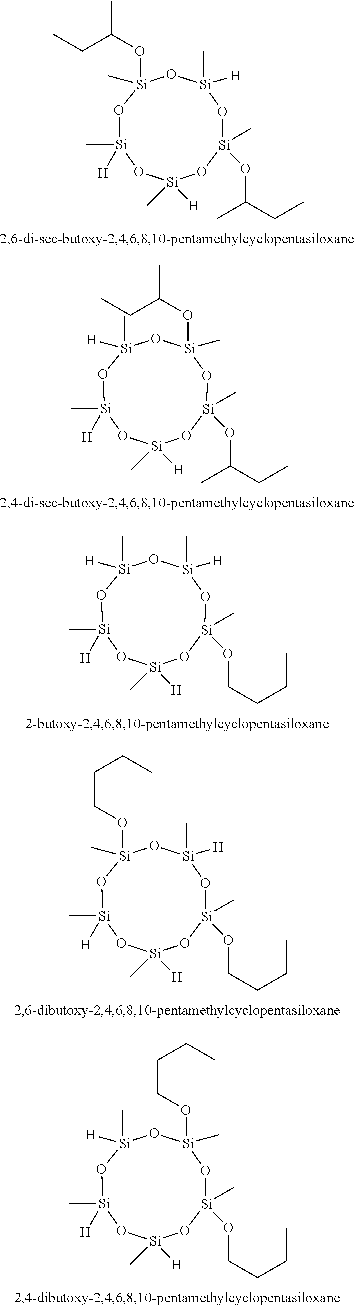

9. The composition according to claim 1, comprising a mixture of compounds of Formula A and Formula B.

10. The composition according to claim 1, comprising a mixture of compounds of Formula A and Formula C.

11. The composition according to claim 1, comprising a mixture of compounds of Formula B and Formula C.

12. The composition according to claim 1, comprising a mixture of compounds of Formula A, Formula B, and Formula C.

13. A method of depositing a silicon-containing film, comprising:
placing a substrate comprising a surface feature into a deposition chamber;
introducing two, or more, molecules of an alkoxy-functionalized cyclosiloxane compound represented by the Formulas A, B, or C, into the deposition chamber, 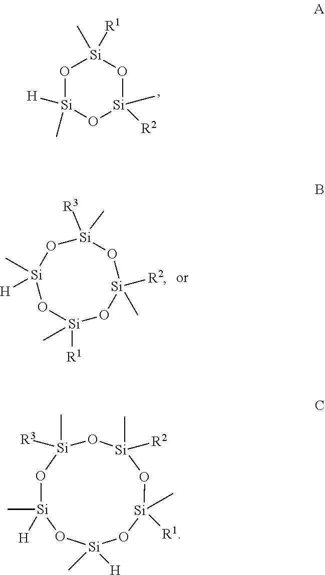
wherein R¹ is an alkoxy-group having 1 to 10 carbon atoms,
wherein R² is H, or is an alkoxy-group having 1 to 10 carbon atoms, and
wherein R³ is H, or is an alkoxy-group having 1 to 10 carbon atoms;
exposing the two, or more, molecules of the alkoxy-functionalized cyclosiloxane compound represented by Formulas A, B, or C, to a plasma in the deposition chamber, thereby inducing a reaction between the two, or more, molecules and thus creating a flowable liquid, or oligomer, made from the two, or more, molecules of the alkoxy-functionalized cyclosiloxane compound represented by Formulas A, B, or C;
permitting the flowable liquid, or oligomer, to at least partially fill the surface feature and thus create the silicon-containing film.

14. The method of depositing a silicon-containing film according to claim 13, wherein the introducing step further comprises introducing an inert gas into the deposition chamber, wherein the inert gas is selected from the group consisting of helium, argon, xenon, and mixtures thereof, wherein the plasma in the exposing step is an in-situ plasma, and wherein atoms of the inert gas are not incorporated into the into the flowable liquid, or oligomer, made from the two, or more, molecules of the alkoxy-functionalized cyclosiloxane compound represented by the Formulas A, B or C, by exposure to the in-situ plasma in the deposition chamber, thereby creating a silicon-containing film comprising silicon and carbon.

15. The method of depositing a silicon-containing film according to claim 13, wherein the introducing step further comprises introducing a nitrogen source into the deposition chamber, wherein the nitrogen source is selected from the group consisting of N₂, ammonia, NF₃, an organoamine, and mixtures thereof, wherein the plasma in the exposing step is an in-situ plasma, and wherein nitrogen atoms of the nitrogen source are incorporated into the flowable liquid, or oligomer, made from the two, or more, molecules of the alkoxy-functionalized cyclosiloxane compound represented by the Formulas A, B or C, by exposure to the in-situ plasma in the deposition chamber, thereby creating a silicon-containing film comprising silicon, carbon, and nitrogen.

16. The method of depositing a silicon-containing film according to claim 13, wherein the introducing step further comprises introducing an oxygen source selected from the group consisting of water, oxygen, ozone, nitric oxide, nitrous oxide, carbon monoxide, carbon dioxide, and combinations thereof, wherein the plasma in the exposing step is an in-situ plasma, and wherein oxygen atoms of the oxygen source are incorporated into the flowable liquid, or oligomer, made from the two, or more, molecules of the alkoxy-functionalized cyclosiloxane compound represented by the Formulas A, B or C, by exposure to the in-situ plasma in the deposition chamber, thereby creating a silicon-containing film comprising silicon, carbon, and oxygen.

17. The method of depositing a silicon-containing film according to claim 13, wherein the plasma in the exposing step is a remote plasma comprising an inert gas, wherein the inert gas is selected from the group consisting of helium, argon, xenon, and mixtures thereof, and wherein atoms of the inert gas are not incorporated into the into the flowable liquid, or oligomer, made from the two, or more, molecules of the alkoxy-functionalized cyclosiloxane compound represented by the Formulas A, B or C, after exposure to the remote plasma in the deposition chamber, thereby creating a silicon-containing film comprising silicon and carbon.

18. The method of depositing a silicon-containing film according to claim 13, wherein the plasma in the exposing step is a remote plasma comprising a nitrogen source, wherein the nitrogen source is selected from the group consisting of N₂, ammonia, NF₃, an organoamine, and mixtures thereof, and wherein nitrogen atoms of the nitrogen source are incorporated into the flowable liquid, or oligomer, made from the two, or more, molecules of the alkoxy-functionalized cyclosiloxane compound represented by the Formulas A, B or C, after exposure to the remote plasma in the deposition chamber, thereby creating a silicon-containing film comprising silicon, carbon, and nitrogen.

19. The method of depositing a silicon-containing film according to claim 13, wherein the plasma in the exposing step is a remote plasma comprising an oxygen source, wherein the oxygen source is selected from the group consisting of water, oxygen, ozone, nitric oxide, nitrous oxide, carbon monoxide, carbon dioxide, and combinations thereof, and wherein oxygen atoms of the oxygen source are incorporated into the flowable liquid, or oligomer, made from the two, or more, molecules of the alkoxy-functionalized cyclosiloxane compound represented by the Formulas A, B or C, after exposure to the remote plasma in the deposition chamber, thereby creating a silicon-containing film comprising silicon, carbon, and oxygen.

20. The method of depositing a silicon-containing film according to claim 13, wherein the substrate is pre-treated in a pre-treatment step before placing it into the deposition chamber, and wherein the pre-treatment step is selected from the group consisting of a plasma treatment, a thermal treatment, a chemical treatment, exposure to ultraviolet light, exposure to an electron beam, and combinations thereof.

21. The method of depositing a silicon-containing film according to claim 13, further comprising a post-treatment in a post-treatment step, and wherein the post-treatment is selected from the group consisting of an ultraviolet cure of the silicon-containing film, a plasma annealing of the silicon-containing film, an infrared treatment of the silicon-containing film, a thermal annealing of the silicon-containing film in non-oxygenated environment, a thermal annealing of the silicon-containing film in an oxygenated environment, and combinations thereof, thereby densifying the silicon-containing film.

22. A film on a substrate, comprising:
a flowable liquid, or oligomer, comprising two, or more, oligomerized, or polymerized, molecules of an alkoxy-functionalized cyclosiloxane compound depicted by Formulas A, B, or C, 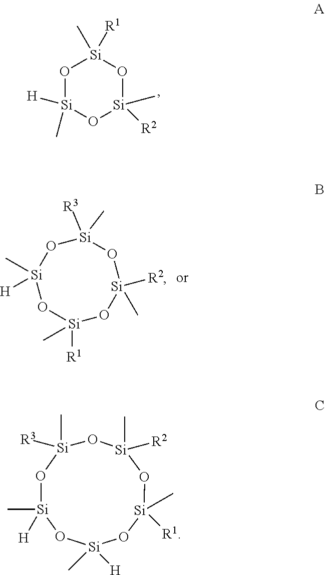
wherein R¹ is an alkoxy-group having 1 to 10 carbon atoms;
wherein R² is H, or is an alkoxy-group having 1 to 10 carbon atoms; and
wherein R³ is H, or is an alkoxy-group having 1 to 10 carbon atoms.
